(19) United States
(12) Patent Application Publication
(10) Pub. No.: US 2023/0023133 A1
(43) Pub. Date: Jan. 26, 2023

(54) SIGNAL PROCESSING DEVICE AND SENSING MODULE

(71) Applicant: Sony Semiconductor Solutions Corporation, Kanagawa (JP)

(72) Inventor: Kenichi Tayu, Kanagawa (JP)

(21) Appl. No.: 17/802,067

(22) PCT Filed: Mar. 25, 2021
(86) PCT No.: PCT/JP2021/012610

§ 371 Date: Aug. 24, 2022

(30) Foreign Application Priority Data
Apr. 9, 2020 (JP) 2020-070412

(51) Int. Cl. G01S 17/894; H03K 19/173; G01S 7/4863; H04N 5/376; H01L 27/146

(52) U.S. Cl. CPC G01S 17/894; H03K 19/1733; G01S 7/4863; H04N 5/376; H01L 27/14603; H01L 27/14636

(57) ABSTRACT

A signal processing device according to the present technology includes a multistage-branching-wired-line unit that supplies the same signal to a plurality of target elements via multistage-branched wired lines, and a logic circuit arranged at each of stages of the multistage-branching-wired-line unit, in which the wired lines in at least a certain space between the stages in the multistage-branching-wired-line unit cross each other.

### TECHNICAL FIELD

The present technology relates to technical fields of a signal processing device including a multistage-branching-wired-line unit that supplies the same signal to a plurality of target elements via multistage-branched wired lines, and a sensing module including the signal processing device.

### BACKGROUND ART

There is a need to propagate the same signal to a plurality of target elements with an equal delay. For example, the case is that, in a sensor device including a pixel array unit in which a plurality of pixels including light reception elements is two-dimensionally arrayed, the same signal (for example, a clock signal or the like) for driving the pixels is propagated, with an equal delay, to a plurality of driving elements for driving each pixel.

Note that Patent Document 1 below can be cited as related conventional techniques. Patent Document 1 discloses a technique for suppressing a delay of a pixel control signal in an image sensor.

### CITATION LIST

### Patent Document

### Patent Document 1: WO 2016/170833 A

### SUMMARY OF THE INVENTION

### Problems to be Solved by the Invention

In order to propagate the same signal to a plurality of target elements with an equal delay, it is effective to make equal the wired-line length to each target element.

As a wired-line structure for securing the equal-length property of the wired lines, a wired-line structure called a tree structure (or also referred to as a tournament structure) is known. In the tree structure, the wired lines are branched in multiple stages. Specifically, the tree structure has a branching chain structure in which each wired line after branching is further branched.

By adopting the tree structure, the lengths of signal supply paths to the plurality of respective target elements can be made equal. That is, it is possible to secure the equal-delay property for signal propagation in terms of securing the equal-length property of the wired-line paths.

However, even if the equal-length property of the wired-line paths is secured by the tree structure, the equal-delay property cannot be secured in some cases.

Since the tree structure is a wired-line structure assuming relatively long wired-line paths to the target elements, logic circuits, such as buffer circuits or inverter circuits, for propagating logic without changing the logic are arranged at each stage of the tree structure. At this time, with respect to power sources for driving the logic circuits, it is often difficult to supply the power source to every logic circuit from an individual supply position due to space constraints and the like. In that case, the power source is supplied to the plurality of logic circuits from a common supply position.

In a case where a configuration in which a power source is supplied to the plurality of logic circuits from the common supply position is adopted as described above, there occur differences between the distances from the common supply position to the logic circuits. At this time, since the logic circuit closer to the common supply position tends to have a shorter wired power-source line and a lower wired-line impedance, the driving force tends to increase. In other words, the logic circuit closer to the common supply position tends to have a lower delay. On the other hand, since the logic circuit farther from the common supply position tends to have a longer wired power-source line and a higher wired-line impedance, and the voltage drop increases, the driving force tends to decrease. That is, the logic circuit farther from the common supply position tends to have a higher delay.

When in the tree structure, the logic circuits with lower delays and the logic circuits with higher delays exist together as described above, a signal supply path passing through only the logic circuits with smaller delay amounts (logic circuits closer to the common supply position), and a signal supply path passing through only the logic circuits with larger delay amounts (logic circuits farther from the common supply position) may exist together, and the equal-delay property of the signals may not be secured. That is, it may be impossible to secure the equal-delay property of the signals although the equal-length property of the wired lines is secured as the tree structure.

The present technology has been made in view of the circumstances described above, and an object thereof is to equalize signal propagation delays in a case where the same signal is propagated to a plurality of target elements.

### Solutions to Problems

A signal processing device according to the present technology includes a multistage-branching-wired-line unit that supplies the same signal to a plurality of target elements via multistage-branched wired lines, and a logic circuit arranged at each of stages of the multistage-branching-wired-line unit, in which the wired lines in at least a certain space between the stages in the multistage-branching-wired-line unit cross each other.

Therefore, it is possible to prevent a path passing through only the logic circuits with smaller delay amounts, and a path passing through only the logic circuits with larger delay amounts from existing together as signal supply paths for the respective target elements.

Conceivable is the signal processing device according to the present technology described above, in which in the multistage-branching-wired-line unit, branching directions of the wired lines coincide with each other in each stage, and a separation distance, in the branching directions, between paired logic circuits that are among logic circuits arranged at at least one of the stages in the multistage-branching-wired-line unit and whose immediately previous wired-line-branching point is common, is different from a separation distance, in the branching directions, between two wired-line-branching points that are among wired-line-branching points in the stage immediately lower than the one of the stages, and are wired-line-branching points from the paired logic circuits.

Therefore, the distance from a power source supply position can be adjusted for the logic circuits arranged at the at least one of the stages.

Conceivable is the signal processing device according to the present technology described above, in which the one of the stages is the stage immediately before the crossing of the wired lines, and the separation distance, in the branching directions, between the paired logic circuits in the one of the stages is shorter than the separation distance, in the branching directions, between the two wired-line-branching points in the stage immediately lower than the one of the stages.

When wired lines in a certain space between stages are crossed for a wired-line tree structure, the wired-line length at the crossing portion extends, and thus the overall wired-line length also increases. As described above, with respect to the separation distance, in the branching directions, the separation distance between the paired logic circuits in the stage immediately before the crossing of the wired lines is made shorter than the separation distance between the two wired-line-branching points in the immediately lower stage, so that the wired-line length required for branching in the stage immediately before the crossing can be shortened, and the overall wired-line length can be shortened.

Conceivable is the signal processing device according to the present technology described above, in which in the multistage-branching-wired-line unit, wired output lines of at least certain logic circuits among the logic circuits arranged at a lowermost one of the stages are short-circuited with each other.

The wired output lines of the logic circuits arranged at the lowermost stage are short-circuited with each other, so that it is possible to equalize signal delays for the target elements connected to the wired output lines. At this time, since in the multistage-branching-wired-line unit, the wired lines in the certain space between the stages are crossed, the wired-line short circuit is in a state where the difference in the delay amounts is suppressed, and it is possible to suppress a through current accompanying the wired-line short circuit.

Conceivable is the signal processing device according to the present technology described above, in which in the lowermost stage, the short-circuiting of the wired output lines with each other is only among certain ones of the wired output lines.

The through current is suppressed by short-circuiting not all but only the certain wired output lines.

Conceivable is the signal processing device according to the present technology described above, in which in the lowermost stage, all the wired output lines are short-circuited with each other.

Therefore, the effect of equalizing the delay amounts due to the wired-line short circuit is enhanced.

Conceivable is the signal processing device according to the present technology described above, in which the wired lines are crossed in a plurality of spaces between the stages in the multistage-branching-wired-line unit.

By performing the wired-line crossing in the plurality of spaces between the stages, the number of adjustment elements of the delay amounts is more increased than a case where the wired-line crossing is performed in only one space between the stages.

Furthermore, a sensing module according to the present technology includes a pixel array unit in which a plurality of pixels including light reception elements is two-dimensionally arrayed, a multistage-branching-wired-line unit that supplies the same signal, via multistage-branched wired lines, to a plurality of driving elements that drives the plurality of pixels in the pixel array unit, and a logic circuit arranged at each of stages of the multistage-branching-wired-line unit, in which the wired lines in at least a certain space between the stages in the multistage-branching-wired-line unit cross each other.

Therefore, it is possible to prevent a path passing through only the logic circuits with smaller delay amounts, and a path passing through only the logic circuits with larger delay amounts from existing together as signal supply paths for the respective driving elements.

Conceivable is the sensing module according to the present technology described above that performs distance measurement by a ToF scheme.

Therefore, in the sensing module that performs distance measurement by the ToF scheme, it is possible to equalize the signal propagation delays for the driving elements.

Conceivable is the sensing module according to the present technology described above, further including a light emission unit that emits light for distance measurement, in which a wired-line path for a light emission timing signal that indicates a light emission timing of the light emission unit is formed along a wired-line path that is among wired-line paths for the same signal in the multistage-branching-wired-line unit and that passes through a crossing portion of the wired lines.

Therefore, the signal propagation delay equalization between a signal for the elements for driving the pixels and the light emission timing signal can be performed.

### BRIEF DESCRIPTION OF DRAWINGS

FIG. 1 is a block diagram for describing a configuration example of a distance measurement apparatus including a signal processing device and a sensing module as an exemplary embodiment according to the present technology.

FIG. 2 is a block diagram illustrating an internal circuit configuration example of a sensor unit in the exemplary embodiment.

FIG. 3 is an explanatory diagram of clocks on the light reception side and the light emission side in the sensing module as the exemplary embodiment.

FIG. 4 is an equivalent-circuit diagram of a pixel included in the sensor unit in the exemplary embodiment.

FIG. 5 is a diagram illustrating an internal configuration example of the signal processing device as the exemplary embodiment, and a positional relationship between components of the signal processing device and a pixel array unit.

FIG. 6 is an explanatory diagram of a multistage-branching-wired-line unit with a tree structure (tournament structure).

FIG. 7 is an explanatory diagram illustrating a case in which the equal-delay property cannot be secured due to an influence of delay amounts of logic circuits.

FIG. 8 is a diagram illustrating a configuration in which a wired output line from each logic circuit at a lowermost stage in the tree structure is short-circuited.

FIG. 9 is an explanatory diagram of a wired-line structure of a multistage-branching-wired-line unit as a first example in the exemplary embodiment.

FIG. 10 is an explanatory diagram of a wired-line structure of a multistage-branching-wired-line unit as a second example in the exemplary embodiment.

FIG. 11 is an explanatory diagram of a wired-line structure of a multistage-branching-wired-line unit as a third example in the exemplary embodiment.

FIG. 12 is an explanatory diagram of a wired-line structure of a multistage-branching-wired-line unit as a fourth example in the exemplary embodiment.

FIG. 13 is an explanatory diagram of a wired-line structure of a multistage-branching-wired-line unit as a modification example of the fourth example.

FIG. 14 is an explanatory diagram of a wired-line structure of a multistage-branching-wired-line unit as a fifth example in the exemplary embodiment.

FIG. 15 is an explanatory diagram of a wired-line structure of a multistage-branching-wired-line unit as a sixth example in the exemplary embodiment.

FIG. 16 is an explanatory diagram of a wired-line structure of a multistage-branching-wired-line unit as a seventh example in the exemplary embodiment.

FIG. 17 is an explanatory diagram of a wired-line structure of a multistage-branching-wired-line unit as an eighth example in the exemplary embodiment.

FIG. 18 is an explanatory diagram of an example of a wired-line-crossing structure.

FIG. 19 is a diagram illustrating an example in which a wired line for a light emission timing signal is disposed along a wired-line path for a light reception timing signal in a tree structure.

FIG. 20 is a diagram illustrating an example of a wired-line structure as a first modification example.

FIG. 21 is an explanatory diagram of a second modification example.

### MODE FOR CARRYING OUT THE INVENTION

Hereinafter, exemplary embodiments according to the present technology will be described in the following order with reference to the accompanying drawings.

<1. Configuration of Distance Measurement Apparatus>

<2. Circuit Configuration of Sensor Unit>

<3. Circuit Configuration of Pixel Array Unit>

<4. About Multistage-Branching-Wired-line Unit>

<5. Multistage-Branching-Wired-Line Unit as Exemplary Embodiment>

[5-1. First Example]

[5-2. Second Example]

[5-3. Third Example]

[5-4. Fourth Example]

[5-5. Fifth Example]

[5-6. Sixth Example]

[5-7. Seventh Example]

[5-8. Eighth Example]

<6. Example of Wired-Line-Crossing Structure>

<7. Modification Examples>

[7-1. First Modification Example]

[7-2. Second Modification Example]

[7-3. Other Modification Examples]

<8. Summary of Exemplary Embodiments>

<9. Present Technology>

### 1. Configuration of Distance Measurement Apparatus

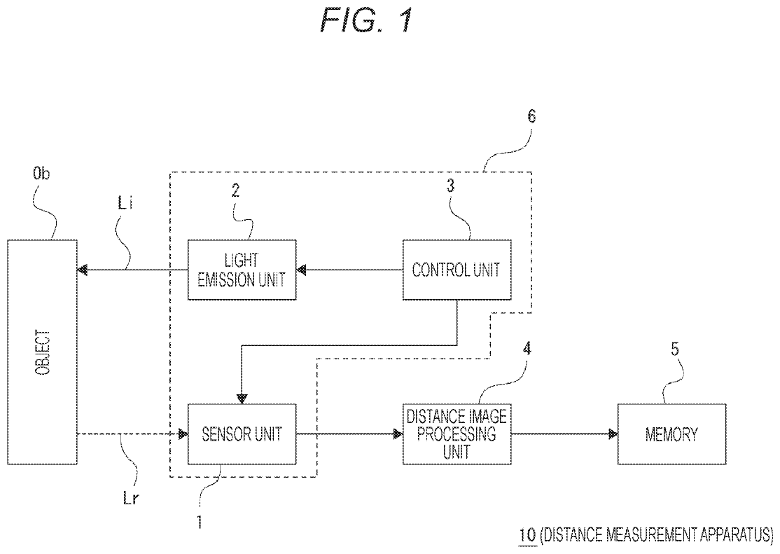

FIG. 1 is a block diagram for describing a configuration example of a distance measurement apparatus 10 including a signal processing device and a sensing module as an exemplary embodiment according to the present technology.

The distance measurement apparatus 10 includes a sensor unit 1, a light emission unit 2, a control unit 3, a distance image processing unit 4, and a memory 5. A sensing module 6 as the exemplary embodiment includes the sensor unit 1, the light emission unit 2, and the control unit 3. The signal processing device as the exemplary embodiment corresponds to a transfer gate driving unit 12 in the sensor unit 1 as described later.

The distance measurement apparatus 10 is an apparatus that performs distance measurement by a Time of Flight (ToF) scheme. Specifically, the distance measurement apparatus 10 of the present example performs distance measurement by an indirect ToF scheme. The indirect ToF scheme is a distance measurement scheme of calculating a distance to an object Ob on the basis of the phase difference between irradiation light Li for the object Ob and reflected light Lr obtained by reflecting the irradiation light Li by the object Ob.

The light emission unit 2 includes one or a plurality of light emission elements as a light source, and emits the irradiation light Li for the object Ob. In the present example, the light emission unit 2 emits, for example, infrared light having a wavelength in a range of 780 nm to 1000 nm as the irradiation light Li.

The control unit 3 controls light emission operation of the irradiation light Li by the light emission unit 2. In a case of the indirect ToF scheme, light whose intensity is modulated so that the intensity changes at a predetermined cycle is used as the irradiation light Li. Specifically, in the present example, pulsed light is repeatedly emitted at a predetermined cycle as the irradiation light Li. Hereinafter, such a light emission cycle of the pulsed light is denoted as a “light emission cycle Cl”. Furthermore, the period between the light emission start timings of the pulsed light during a time when the pulsed light is repeatedly emitted in the light emission cycle Cl is denoted as “one modulation period Pm” or simply a “modulation period Pm”.

The control unit 3 controls the light emission operation of the light emission unit 2 so that the light emission unit 2 emits the irradiation light Li only during a predetermined light emission period in every modulation period Pm.

Here, in the indirect ToF scheme, the light emission cycle Cl is made relatively fast, for example, about several tens of MHz to several hundreds of MHz.

The sensor unit 1 receives the reflected light Lr and outputs distance measurement information by the indirect ToF scheme on the basis of the phase difference between the reflected light Lr and the irradiation light Li.

As will be described later, the sensor unit 1 of the present example includes a pixel array unit 11 in which a plurality of pixels Px including a photoelectric conversion element (photodiode PD), and a first transfer gate element (transfer transistor TG-A) and a second transfer gate element (transfer transistor TG-B) for transferring an accumulated charge of the photoelectric conversion element is two-dimensionally arrayed, and obtains distance measurement information by the indirect ToF scheme for every pixel Px.

Note that hereinafter, the information indicating the distance measurement information (distance information) for every pixel Px as described above is denoted as a “distance image”.

Here, as is publicly known, in the indirect ToF scheme, a signal charge accumulated in the photoelectric conversion element in the pixel Px is distributed to two floating diffusions (FD) by the first transfer gate element and the second transfer gate element which are alternately turned on. At this time, the cycle in which the first transfer gate element and the second transfer gate element are alternately turned on is the same cycle as the light emission cycle Cl of the light emission unit 2. That is, the first transfer gate element and the second transfer gate element are each turned on once in every modulation period Pm, and the distribution of the signal charge to the two floating diffusions as described above is repeatedly performed in every modulation period Pm.

In the present example, the transfer transistor TG-A as the first transfer gate element is on in the light emission period of the irradiation light Li in the modulation period Pm, and the transfer transistor TG-B as the second transfer gate element is on in a non-light emission period of the irradiation light Li in the modulation period Pm.

As described above, since the light emission cycle Cl is made relatively fast, a signal charge accumulated in each floating diffusion by one distribution using the first and second transfer gate elements as described above is a relatively small amount. Therefore, in the indirect ToF scheme, the emission of the irradiation light Li is repeated about several thousand times to several tens of thousands of times per distance measurement (that is, in obtaining one distance image), and while the irradiation light Li is repeatedly emitted in this manner, the distribution of the signal charge to each floating diffusion using the first and second transfer gate elements, as described above, is repeatedly performed in the sensor unit 1.

As understood from the above description, in the sensor unit 1, for every pixel Px, the first transfer gate element and the second transfer gate element are driven at timings synchronized with the light emission cycle of the irradiation light Li. For this synchronization, the control unit 3 controls light reception operation by the sensor unit 1 and light emission operation by the light emission unit 2 on the basis of a common clock as described later.

The distance image obtained by the sensor unit 1 is input into the distance image processing unit 4. The distance image processing unit 4 applies predetermined signal processing, such as compression encoding, to the distance image, and outputs the applied distance image to the memory 5.

The memory 5 is a storage device, such as a flash memory, a solid state drive (SSD), or a hard disk drive (HDD), and stores the distance image processed by the distance image processing unit 4.

### 2. Circuit Configuration of Sensor Unit

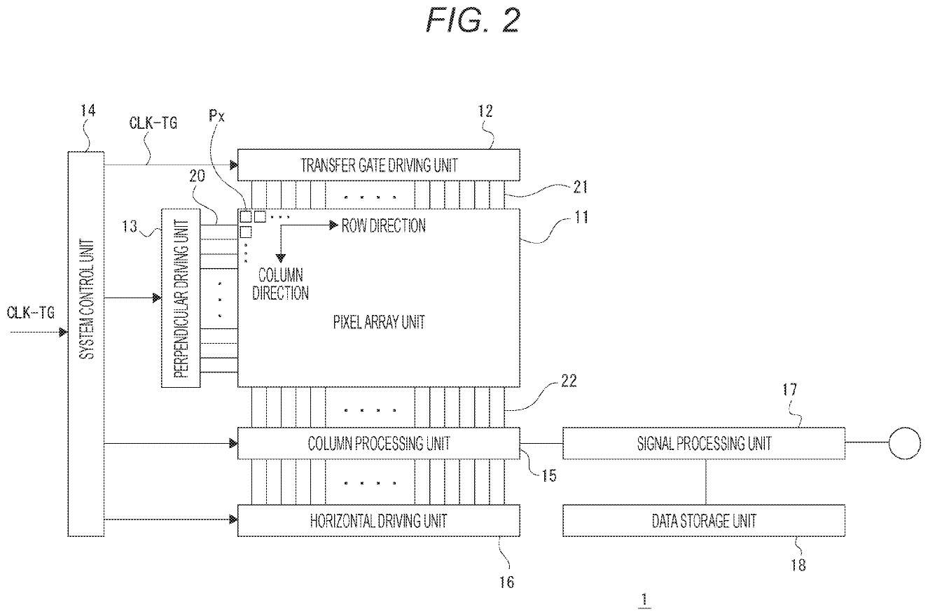

FIG. 2 is a block diagram illustrating an internal circuit configuration example of the sensor unit 1.

As illustrated, the sensor unit 1 includes the pixel array unit 11, the transfer gate driving unit 12, a perpendicular driving unit 13, a system control unit 14, a column processing unit 15, a horizontal driving unit 16, a signal processing unit 17, and a data storage unit 18.

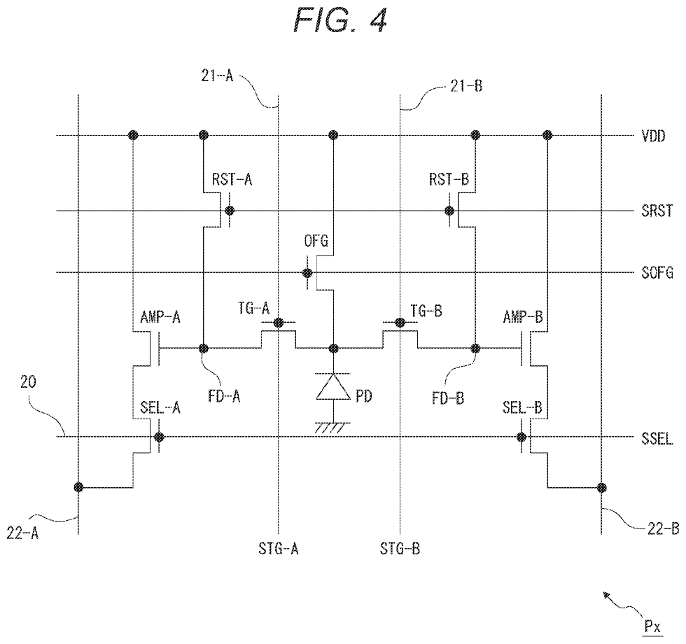

The pixel array unit 11 has a configuration in which the plurality of pixels Px is two-dimensionally arrayed in a matrix in a row direction and a column direction. Each pixel Px includes a photodiode PD described later, as the photoelectric conversion element. Note that details of the pixel Px will be described again with reference to FIG. 4.

Here, the row direction refers to an array direction of the pixels Px in a horizontal direction, and the column direction refers to an array direction of the pixels Px in a perpendicular direction. In the drawing, the row direction is a lateral direction, and the column direction is a vertical direction.

In the pixel array unit 11, for the matrix-like pixel array, a row driving line 20 is wired for every pixel row along the row direction, and two gate driving lines 21 and two perpendicular signal lines 22 are wired for each pixel column, each along the column direction. For example, the row driving line 20 transmits a driving signal for performing driving when a signal is read out from the pixel Px. Note that in FIG. 2, the row driving line 20 is illustrated as one wired line, but is not limited to one. One end of the row driving line 20 is connected to an output terminal of the perpendicular driving unit 13 corresponding to each row.

The system control unit 14 includes a timing generator that generates various timing signals, and the like. On the basis of the various timing signals generated by the timing generator, the system control unit 14 performs driving control of the transfer gate driving unit 12, the perpendicular driving unit 13, the column processing unit 15, the horizontal driving unit 16, and the like.

On the basis of the control of the system control unit 14, the transfer gate driving unit 12 drives two transfer gate elements, provided for every pixel Px, through the two gate driving lines 21 provided for each pixel column as described above.

As described above, the two transfer gate elements are alternately turned on in every modulation period Pm. Therefore, the system control unit 14 supplies a light-reception-side clock signal CLK-TG input from the control unit 3 illustrated in FIG. 1 to the transfer gate driving unit 12, and the transfer gate driving unit 12 drives the two transfer gate elements on the basis of the light-reception-side clock signal CLK-TG.

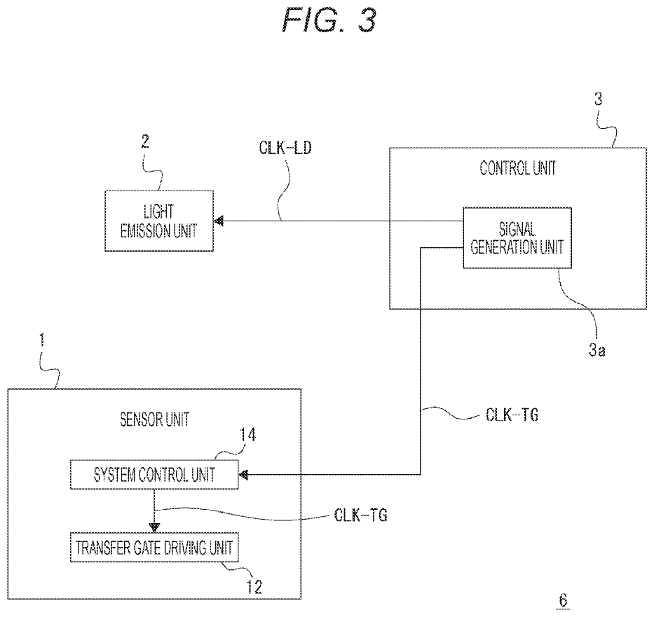

Here, the relationship between clocks on the light reception side and the light emission side in the sensing module 6 will be described with reference to FIG. 3.

As illustrated in FIG. 3, the control unit 3 is provided with a signal generation unit 3a that generates a light-emission-side clock signal CLK-LD, which is a clock signal indicating the light emission timing of the light emission unit 2, and a light-reception-side clock signal CLK-TG for the sensor unit 1. The signal generation unit 3a includes an oscillator, and outputs clock signals generated by the oscillator, as the light-emission-side clock signal CLK-LD and the light-reception-side clock signal CLK-TG, to the light emission unit 2, and the system control unit 14 of the sensor unit 1, respectively.

In FIG. 2, the perpendicular driving unit 13 includes a shift register, an address decoder, and the like, and drives the pixels Px of the pixel array unit 11 on a simultaneously-all-pixel basis, a row-by-row basis, or the like. That is, the perpendicular driving unit 13, together with the system control unit 14 that controls the perpendicular driving unit 13, constitutes a driving unit that controls operation of each pixel Px of the pixel array unit 11.

Detection signals output (read out) from each pixel Px of a pixel row according to the driving control by the perpendicular driving unit 13, specifically, signals corresponding to signal charges accumulated in the two floating diffusions, respectively, provided for every pixel Px are input into the column processing unit 15 through the corresponding perpendicular signal lines 22. The column processing unit 15 performs predetermined signal processing to the detection signals read out from each pixel Px through the perpendicular signal lines 22, and temporarily holds the detection signals after the signal processing. Specifically, as the signal processing, the column processing unit 15 performs noise removal processing, analog to digital (A/D) conversion processing, and the like.

Here, the reading out of two detection signals from each pixel Px (a detection signal of every floating diffusion) is performed once out of every predetermined number of times of repeated light emission of the irradiation light Li (every several thousands to several tens of thousands of times of repeated light emission described above).

Therefore, the system control unit 14 controls the perpendicular driving unit 13 on the basis of the light-reception-side clock signal CLK-TG to perform control so that the reading timing of the detection signals from each pixel Px becomes the timing out of every predetermined number of times of repeated light emission of the irradiation light Li in this manner.

The horizontal driving unit 16 includes a shift register, an address decoder, and the like, and sequentially selects unit circuits corresponding to the pixel columns of the column processing unit 15. By the selective scanning by the horizontal driving unit 16, the detection signals subjected to the signal processing for every unit circuit in the column processing unit 15 are sequentially output.

The signal processing unit 17 has at least an arithmetic processing function, and performs various signal processing, such as calculation processing of a distance corresponding to the indirect ToF scheme, on the basis of the detection signals output from the column processing unit 15. Note that a publicly known technique can be used as a technique of calculating distance information by the indirect ToF scheme on the basis of two types of detection signals for every pixel Px (detection signals of every floating diffusion), and the description will be omitted here.

The data storage unit 18 temporarily stores data necessary for the signal processing in the signal processing unit 17.

The sensor unit 1 configured as described above outputs a distance image indicating the distance to the object Ob for every pixel Px. The distance measurement apparatus 10 including such a sensor unit 1 can be applied to, for example, an in-vehicle system that is mounted on a vehicle and measures a distance to an object Ob outside the vehicle, a gesture recognition apparatus that measures a distance to an object, such as a hand of a user, and recognizes a gesture of the user on the basis of the measurement result, and the like.

### 3. Circuit Configuration of Pixel Array Unit

FIG. 4 illustrates an equivalent circuit of the pixel Px two-dimensionally arrayed in the pixel array unit 11.

The pixel Px includes one photodiode PD as the photoelectric conversion element, and one overflow (OF) gate transistor OFG. Furthermore, the pixel Px includes two transfer transistors TG as the transfer gate elements, two floating diffusions FD, two reset transistors RST, two amplification transistors AMP, and two selection transistors SEL.

Here, in a case where the two transfer transistors TG, the two floating diffusions FD, the two reset transistors RST, the two amplification transistors AMP, and the two selection transistors SEL provided in the pixel Px are distinguished from each other, they are denoted as transfer transistors TG-A and TG-B, floating diffusions FD-A and FD-B, reset transistors RST-A and RST-B, amplification transistors AMP-A and AMP-B, and selection transistors SEL-A and SEL-B, as illustrated in FIG. 4.

The OF gate transistor OFG, the transfer transistors TG, the reset transistors RST, the amplification transistors AMP, and the selection transistors SEL include, for example, N-type MOS transistors.

When an OF gate signal SOFG supplied to the gate of the OF gate transistor OFG is turned on, the OF gate transistor OFG is into a conductive state. When the OF gate transistor OFG is into a conductive state, the photodiode PD is clamped at a predetermined reference potential VDD, and the accumulated charge is reset.

Note that the OF gate signal SOFG is supplied from the perpendicular driving unit 13, for example.

When a transfer driving signal STG-A supplied to the gate of the transfer transistor TG-A is turned on, the transfer transistor TG-A is into a conductive state and transfers a signal charge accumulated in the photodiode PD to the floating diffusion FD-A. When a transfer driving signal STG-B supplied to the gate of the transfer transistor TG-B is turned on, the transfer transistor TG-B is into a conductive state and transfers a charge accumulated in the photodiode PD to the floating diffusion FD-B.

The transfer driving signals STG-A and STG-B are supplied from the transfer gate driving unit 12 through gate driving lines 21A and 21B each provided as one of the gate driving lines 21 illustrated in FIG. 2.

The floating diffusions FD-A and FD-B are charge holding units that temporarily hold the charges transferred from the photodiode PD.

When a reset signal SRST supplied to the gate of the reset transistor RST-A is turned on, the reset transistor RST-A is into a conductive state and resets the potential of the floating diffusion FD-A to the reference potential VDD. Similarly, a reset signal SRST supplied to the gate of the reset transistors RST-B is turned on, so that the reset transistor RST-B is into a conductive state and resets the potential of the floating diffusion FD-B to the reference potential VDD.

Note that the reset signal SRST is supplied from the perpendicular driving unit 13, for example.

The source of the amplification transistor AMP-A is connected to a perpendicular signal line 22-A via the selection transistor SEL-A, and the drain of the amplification transistor AMP-A is connected to the reference potential VDD (constant current source) to constitute a source follower circuit. The source of the amplification transistor AMP-B is connected to a perpendicular signal line 22-B via the selection transistor SEL-B, and the drain of the amplification transistor AMP-B is connected to the reference potential VDD (constant current source) to constitute a source follower circuit.

Here, the perpendicular signal lines 22-A and 22-B are each provided as one of the perpendicular signal lines 22 illustrated in FIG. 2.

The selection transistor SEL-A is connected to between the source of the amplification transistor AMP-A and the perpendicular signal line 22-A. When a selection signal SSEL supplied to the gate of the selection transistor SEL-A is turned on, the selection transistor SEL-A is into a conductive state and outputs a charge held in the floating diffusion FD-A to the perpendicular signal line 22-A via the amplification transistor AMP-A.

The selection transistor SEL-B is connected to between the source of the amplification transistor AMP-B and the perpendicular signal line 22-B. When a selection signal SSEL supplied to the gate of the selection transistor SEL-B is turned on, the selection transistor SEL-B is into a conductive state and outputs a charge held in the floating diffusion FD-B to the perpendicular signal line 22-B via the amplification transistor AMP-A.

Note that the selection signal SSEL is supplied from the perpendicular driving unit 13 via the row driving line 20.

The operation of the pixel Px will be briefly described.

First, before light reception is started, a reset operation for resetting an electric charge of the pixel Px is performed in all the pixels. That is, for example, the OF gate transistor OFG, each reset transistor RST, and each transfer transistor TG are turned on (conductive states), and accumulated charges of the photodiode PD and each floating diffusion FD are reset.

After the resetting of the accumulated charges, light reception operation for distance measurement is started in all the pixels. The light reception operation here means light reception operation performed for one distance measurement. That is, during the light reception operation, the operation of alternately turning on the transfer transistors TG-A and TG-B is repeated the predetermined number of times (in the present example, about several thousand times to several tens of thousands of times). Hereinafter, such a period of the light reception operation performed for one distance measurement is denoted as a “light reception period Pr”.

In the light reception period Pr, in the one modulation period Pm of the light emission unit 2, for example, after a period in which the transfer transistor TG-A is on (that is, a period in which the transfer transistor TG-B is off) is continued over a light emission period of the irradiation light Li, a remaining period, that is, a non-light emission period of the irradiation light Li, is a period in which the transfer transistor TG-B is on (that is, a period in which the transfer transistor TG-A is off). That is, in the light reception period Pr, the operation of distributing a charge of the photodiode PD to the floating diffusions FD-A and FD-B is repeated the predetermined number of times within the one modulation period Pm.

Then, when the light reception period Pr ends, each pixel Px of the pixel array unit 11 is sequentially selected on a line-by-line basis. In the selected pixel Px, the selection transistors SEL-A and SEL-B are turned on. Therefore, a charge accumulated in the floating diffusion FD-A is output into the column processing unit 15 via the perpendicular signal line 22-A. Furthermore, a charge accumulated in the floating diffusion FD-B is output into the column processing unit 15 via the perpendicular signal line 22-B.

As described above, the one light reception operation ends, and the next light reception operation starting from the reset operation is executed.

Here, the reflected light received by the pixel Px is delayed according to the distance to the object Ob from the timing at which the light emission unit 2 emits the irradiation light Li. Since a distribution ratio of charges accumulated in the two floating diffusions FD-A and FD-B changes due to the delay time according to the distance to the object Ob, the distance to the object Ob can be determined from the distribution ratio of the charges accumulated in the two floating diffusions FD-1 and FD-B.

### 4. About Multistage-Branching-Wired-Line Unit

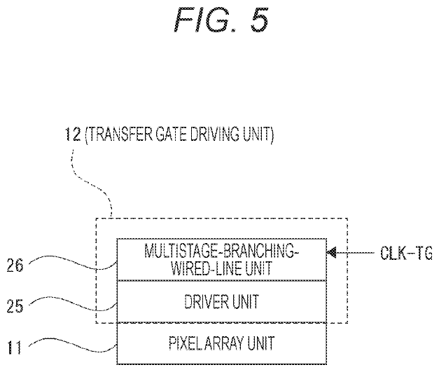

FIG. 5 is a diagram illustrating an internal configuration example of the transfer gate driving unit 12, and illustrating the positional relationship between each component in the transfer gate driving unit 12 and the pixel array unit 11 (positional relationship in a thickness direction of the sensor unit 1).

As illustrated, the transfer gate driving unit 12 includes a driver unit 25 and a multistage-branching-wired-line unit 26. The driver unit 25 includes a plurality of driving elements for driving the transfer transistors TG in each pixel Px of the pixel array unit 11. Although not illustrated, the plurality of driving elements included in the driver unit 25 in this manner is denoted as “driving elements Ed” below.

The multistage-branching-wired-line unit 26 is a wired-line unit for propagating the same signal, as the light-reception-side clock signal CLK-TG, to each driving element Ed in the driver unit 25.

The multistage-branching-wired-line unit 26 has a structure in which wired lines are multistage-branched so as to secure the equal-length property of the wired-line paths of the light-reception-side clock signal CLK-TG for each driving element Ed.

Here, in the present description, the “multistage branching” means that branching of wired lines is performed in multiple stages by at least partially including a branching chain structure in which each wired line after branching is further branched.

In the thickness direction of the sensor unit 1, the driver unit 25 is formed on the pixel array unit 11, and the multistage-branching-wired-line unit 26 is formed on the driver unit 25.

### 5. Multistage-Branching-Wired-Line Unit as Exemplary Embodiment

### 5-1. First Example

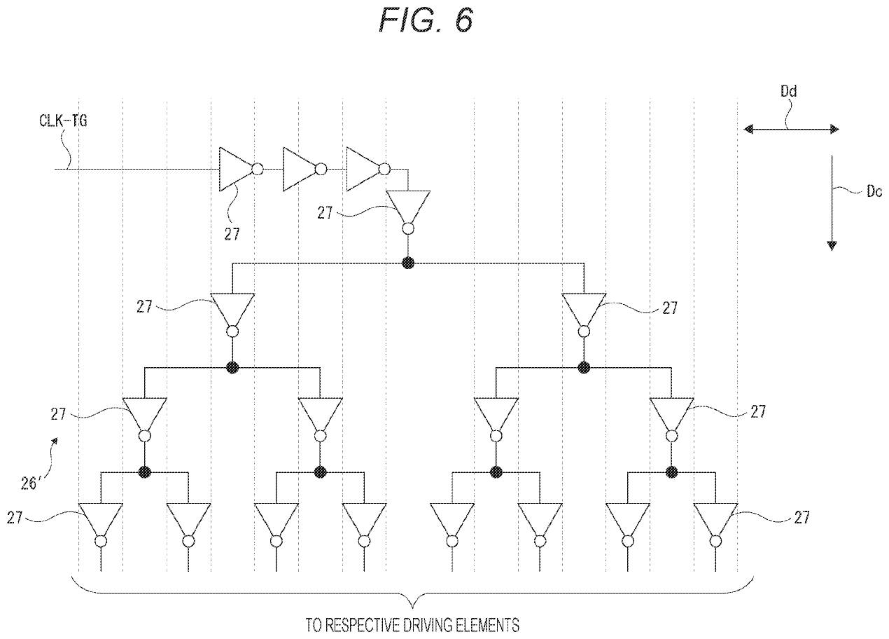

First, prior to the description of the multistage-branching-wired-line unit 26 as an exemplary embodiment, a multistage-branching-wired-line unit 26′ having a conventional tree structure (or also called a tournament structure) will be described with reference to FIG. 6.

As illustrated in FIG. 6, the tree structure has a branching chain structure in which each wired line after branching is further branched, as a branching structure of the wired lines. In the drawing, the tree structure in which the number of stages of the branching is three is illustrated.

Here, regarding the number of stages of the branching, the stage at which first branching is performed is counted as a first stage.

In the tree structure, branching directions of the wired lines in each stage coincide with each other. Hereinafter, the branching directions of the wired lines are denoted as “branching directions Dd”, as illustrated in the drawing. Furthermore, in the branching chain structure due to the multistage branching, a direction in which branching is chained to each other is denoted as a “branching chain direction Dc”, as illustrated in the drawing.

On the wired-line path to each driving element Ed, logic circuits 27 for propagating a signal without changing logic are arranged. Specifically, in the drawing, an example in which inverter circuits are arranged as the logic circuits 27 is illustrated. In a case of adopting the multistage branching structure of the wired lines, every time the wired lines are branched, the logic circuits 27 are each arranged on each wired line after the branching. Therefore, the logic circuits 27 are arranged at each stage in the multistage branching structure, as illustrated in the drawing.

In the multistage-branching-wired-line unit 26′ having the tree structure, the logic circuits 27 are arranged at equal intervals in the branching directions Dd at a lowermost stage. Then, in the multistage-branching-wired-line unit 26′, such arrangement intervals of the logic circuits 27 in the lowermost stage are a standard to determine the arrangement positions, in the branching directions Dd, of the logic circuits 27 of each stage upper than the lowermost stage. Specifically, the arrangement position, in the branching directions Dd, of the logic circuit 27 in a stage immediately upper than the lowermost stage is determined at the center position between the arrangement positions, in the branching directions Dd, of the two logic circuits 27 that are among the logic circuits 27 in the lowermost stage and whose wired-line paths are direct to the logic circuit 27 in question in the immediately upper stage.

Note that the logic circuits 27 whose wired-line paths are direct to a particular logic circuit 27 mean the logic circuit 27 located on each wired line branched from the particular logic circuit 27.

For each stage further upper than the stage immediately upper than the lowermost stage, the position, in the branching directions Dd, of the logic circuit 27 is also determined by a similar knack on the basis of the arrangement positions of the two logic circuits 27 that are in the immediately lower stage and whose wired-line paths are direct.

Therefore, in each stage, the lengths of the two wired lines branched from the logic circuit 27 can be made equal, and an equal-length property can be secured for a wired-line path of the light-reception-side clock signal CLK-TG for each driving element Ed.

However, even if the equal-wired-line-length property is secured as described above, the equal-delay property may not be secured. Particularly in a case where the multistage-branching-wired-line unit is applied to signal propagation for driving the pixels in the sensor unit 1 as in the present example, the equal-delay property may not be secured due to the influence of the delay amounts of the logic circuits 27.

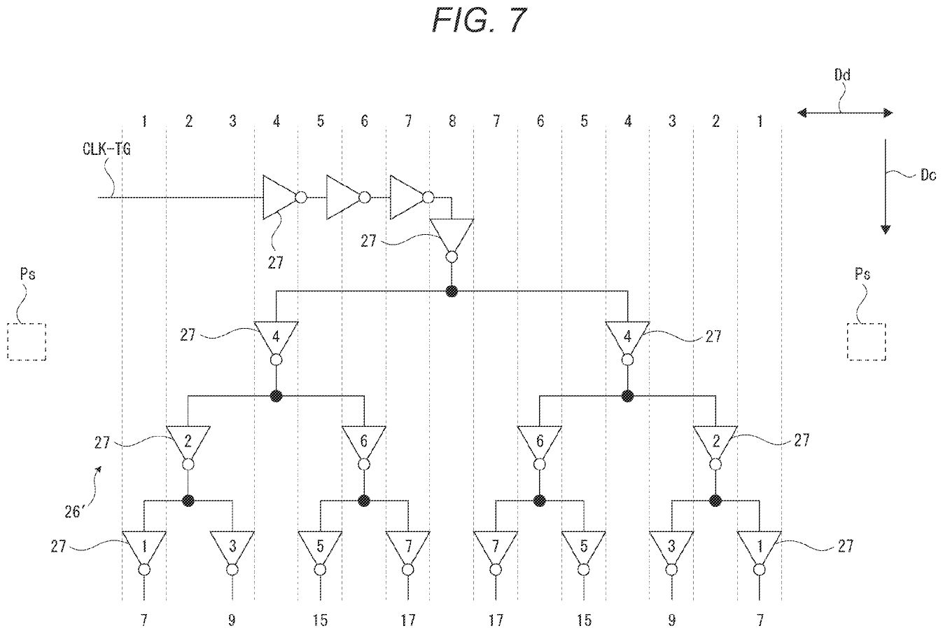

This point will be described with reference to FIG. 7.

As described above, with respect to power sources for driving the logic circuits 27, it is often difficult to supply the power source to every logic circuit from an individual supply position due to space constraints and the like. Particularly in a case of application to signal propagation for driving the pixels in the sensor unit 1, most of a wired-line pair of the power source and a ground (GND) is allocated to the driver unit 25 having large power consumption. Therefore, for the tree structure, power source supply to the plurality of logic circuits 27 is performed from common supply positions.

In the drawing, such common common positions are schematically represented as “supply positions Ps”. As in the illustrated example, the supply positions Ps are located at both ends (both sides), in the branching directions Dd, of the tree structure (multistage branching structure).

In a case where a configuration in which power sources are supplied to the plurality of logic circuits 27 from the common supply positions Ps is adopted as described above, there occur differences between the distances from the supply position Ps to the logic circuits 27. At this time, since the logic circuit 27 closer to the supply position Ps tends to have a shorter wired power-source line and a lower wired-line impedance, the driving force tends to increase. In other words, the logic circuit 27 closer to the supply position Ps tends to have a lower delay. On the other hand, since the logic circuit 27 farther from the supply position Ps tends to have a longer wired power-source line and a higher wired-line impedance, and the voltage drop increases, the driving force tends to decrease. That is, the logic circuit farther from the supply position Ps tends to have a higher delay.

In the drawing, for each logic circuit 27 arranged in the multistage-branching-wired-line unit 26′, the distance, in the branching directions Dd, between the logic circuit 27 and the supply position Ps is numerically expressed. Specifically, the distance of each logic circuit 27 from the supply position Ps is represented with the distance of the logic circuit 27 closest to the supply position Ps as “1”. A larger numerical value means a larger distance.

According to the notation of the distance, the delay amount of each logic circuit 27 in the first stage can be denoted as “4”, the delay amount of the logic circuit 27 in the second stage on the outside of the tree structure can be denoted as “2”, and the delay amount of the logic circuit 27 in the second stage on the inside of the tree structure can be denoted as “6”. Furthermore, the delay amounts of the logic circuits 27 of the third stage can be denoted as “1”, “3”, “5”, and “7” from the outside to the inside of the tree structure, respectively.

Accordingly, in the multistage-branching-wired-line unit 26′ adopting the conventional tree structure, a delay represented by “7”, “9”, “15”, or “17” is generated as a signal delay for each driving element Ed as illustrated in the drawing due to the influence of the delay generated in each logic circuit 27. That is, it is not possible to secure the equal-delay property of the signals although the equal-length property of the wired lines is secured as the tree structure.

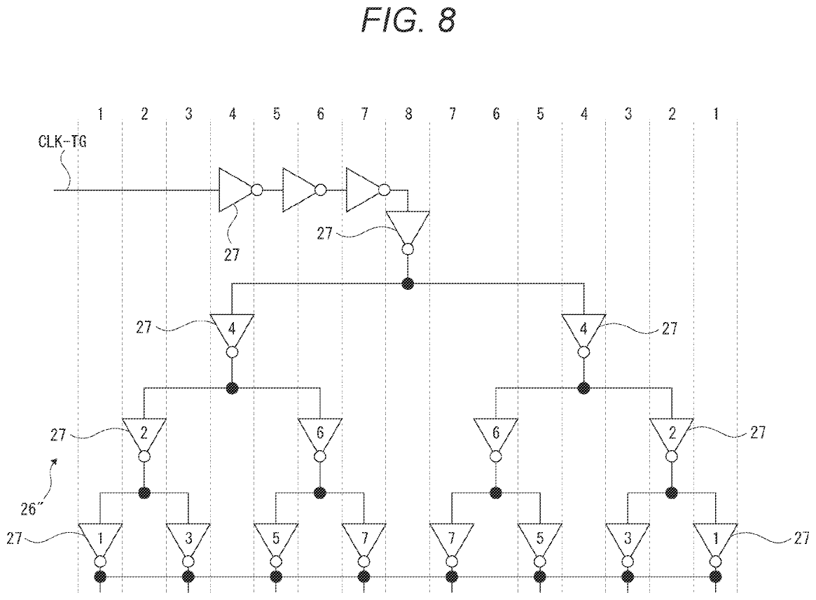

Here, in order to secure the equal-delay property, it is also possible to adopt a configuration in which a wired output line from each logic circuit 27 of a lowermost stage is short-circuited as in a multistage-branching-wired-line unit 26″ illustrated in FIG. 8. By adopting such a configuration, wired-line paths with smaller delay amounts can also supply signals to driving elements Ed connected to wired-line paths with large delay amounts, and the delay amounts can be equalized.

However, in a case where such a wired-line short-circuiting technique is adopted, a through current flows from the wired-line path side with smaller delay amounts to the wired-line path side with larger delay amounts, and wired-line loads in the wired-line paths with smaller delay amounts increase, which leads to an increase in power consumption.

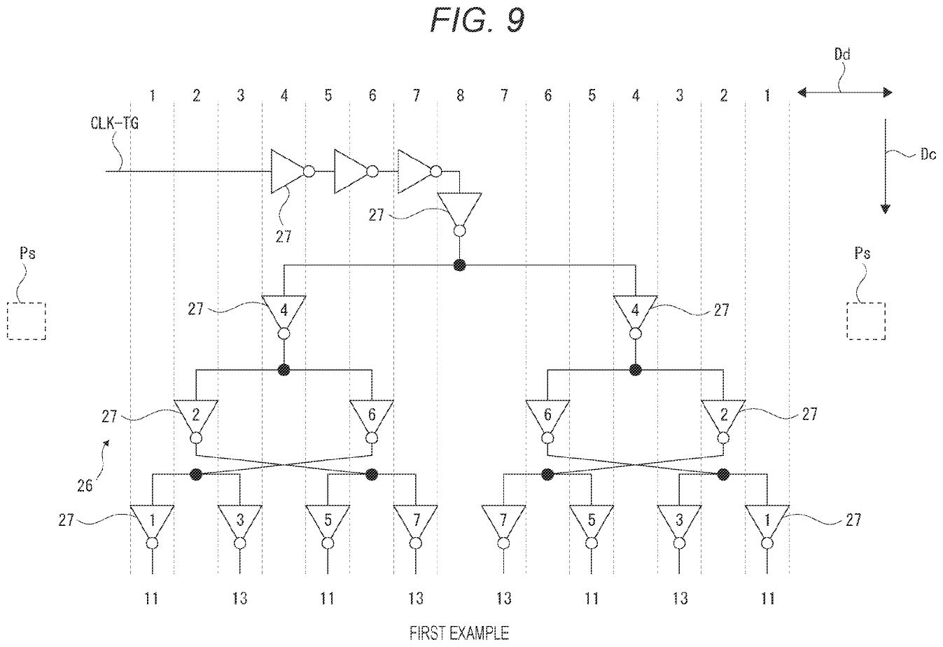

Therefore, in the present exemplary embodiment, as in the multistage-branching-wired-line unit 26 as a first example illustrated in FIG. 9, a technique of crossing wired lines in at least a certain space between stages is adopted.

FIG. 9 illustrates an example in which wired lines are crossed in a space between a second stage and a third stage, as an example of wired-line crossing. In the multistage-branching-wired-line unit 26, the arrangement positions of the logic circuits 27 in each stage are the same as in the case of the multistage-branching-wired-line unit 26′.

Due to such wired-line crossing, it is possible to prevent formation of a wired-line path passing through only the logic circuit 27 with a smaller delay amount in each stage (wired-line paths with a delay amount of “7” in FIG. 7), and a wired-line path passing through only the logic circuit 27 with a larger delay amount in each stage (wired-line paths with a delay amount of “17” in FIG. 7). Therefore, the signal propagation delays for the driving elements Ed can be equalized.

Specifically, the delay amount of a signal for each driving element Ed in this case is “11”, “13”, “11”, or “13” as illustrated, and it can be seen that the delay amounts are equalized as compared with the case of the multistage-branching-wired-line unit 26′ having the tree structure illustrated in FIG. 6.

### 5-2. Second Example

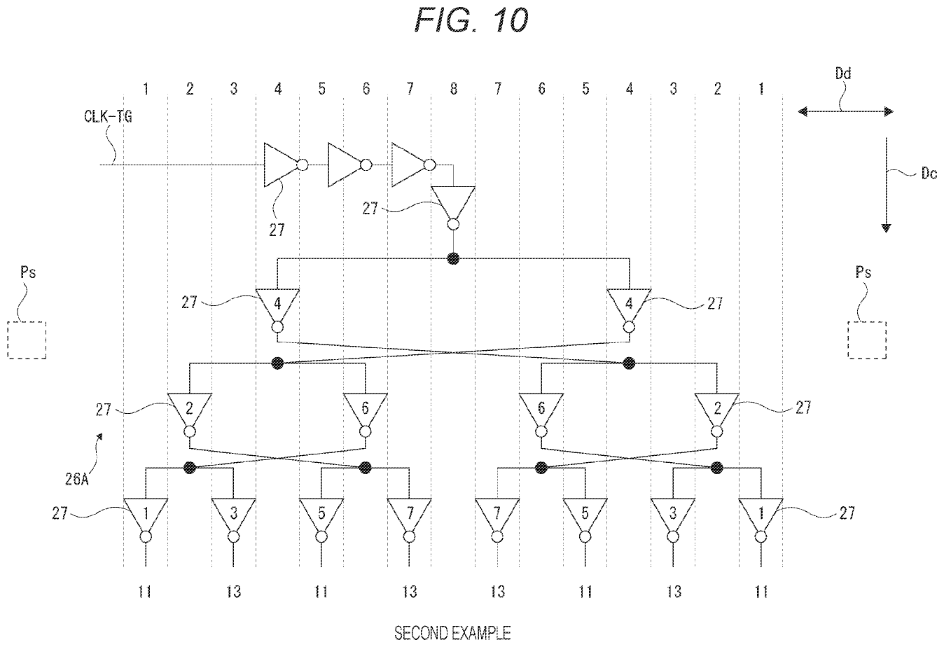

FIG. 10 is an explanatory diagram of a wired-line structure of a multistage-branching-wired-line unit 26A as a second example.

In the multistage-branching-wired-line unit 26A, wired lines are crossed in a plurality of spaces between stages. Specifically, in the illustrated example, wired-line crossing is performed in a space between a first stage and a second stage, and in a space between the second stage and a third stage.

Note that for logic circuits 27 in the first stage, the distance from supply positions Ps can be made equal, that is, the delay amounts can be made equal. Therefore, it is not essential to cross wired lines in the space between the first stage and the second stage in order to equalize the delay amounts.

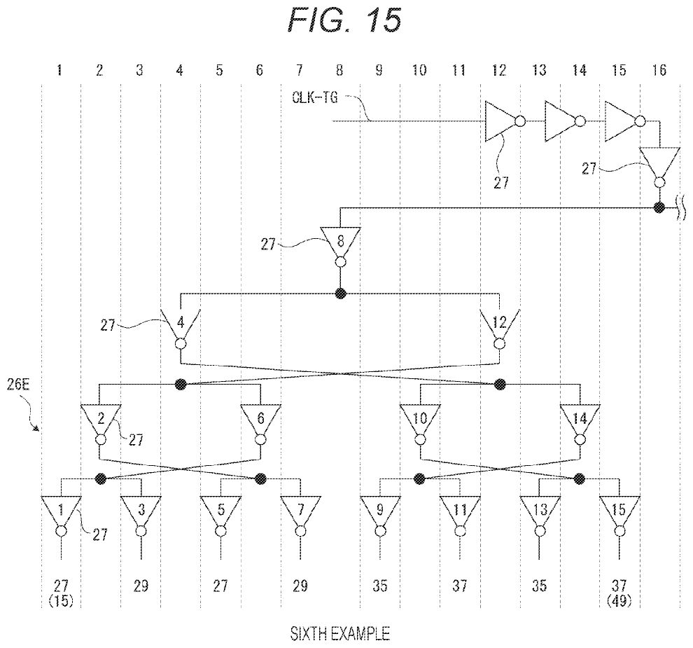

The significance of crossing wired lines in a plurality of spaces between stages will be described in a later sixth example (see FIG. 15).

### 5-3. Third Example

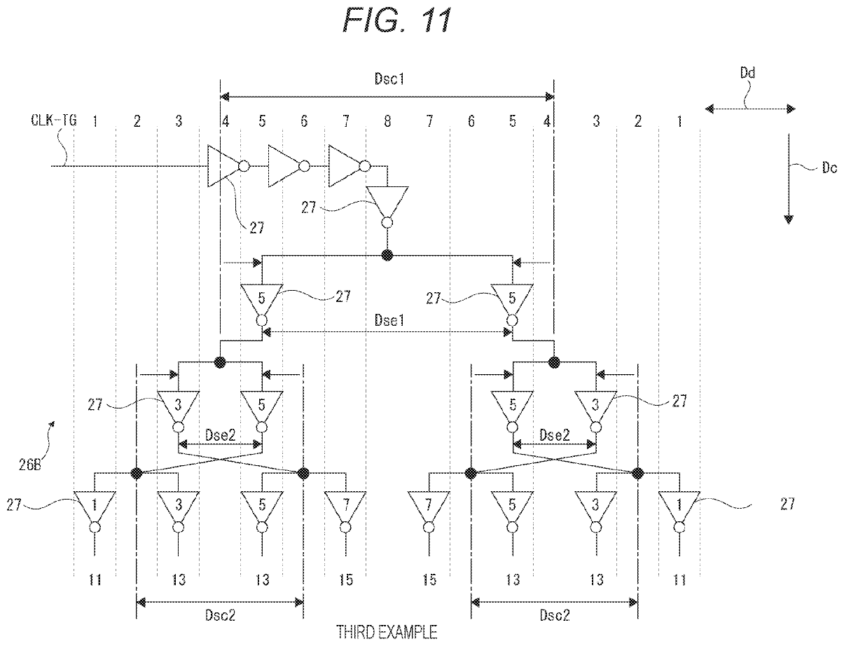

FIG. 11 is an explanatory diagram of a wired-line structure of a multistage-branching-wired-line unit 26B as a third example.

In the multistage-branching-wired-line unit 26B, in at least one stage, the arrangement positions, in the branching directions, of the logic circuits 27 are positions different from the arrangement positions in the cases of the multistage-branching-wired-line unit 26′ and the multistage-branching-wired-line unit 26.

Specifically, for the logic circuits 27 in the target stage, the positions in the branching directions Dd are offset from the positions in the cases of the multistage-branching-wired-line units 26′ and 26, in an inward direction or an outward direction of the multistage branching structure.

In the drawing, an example is illustrated in which the targets for offsetting the positions of the logic circuits 27 in this manner are a first stage and a second stage, but a separation distance Dse1, in the branching directions Dd, between the logic circuits 27 of the first stage coincides with a separation distance Dsc1 illustrated in the drawing, in the cases of the multistage-branching-wired-line unit 26′ and the multistage-branching-wired-line unit 26 (see FIGS. 7 and 9). Here, the separation distance Dsc1 is a separation distance, in the branching directions Dd, between wired-line-branching points from the first stage to the second stage. In other words, the separation distance Dsc1 is the separation distance between a wired-line-branching point from one of the logic circuits 27 in the first stage to the second stage, and a wired-line-branching point from the other logic circuit 27 in the first stage to the second stage.

As illustrated, with respect to the first stage, the separation distance Dse1 between the logic circuits 27 is different from the separation distance Dsc1. Specifically, in this case, the separation distance Dse1 between the logic circuits 27 in the first stage is shorter than the separation distance Dsc1. As a result, each logic circuit 27 of the first stage is arranged at a position offset in the inward direction of the multistage branching structure, as compared with the cases of the multistage-branching-wired-line units 26′ and 26.

Therefore, each logic circuit 27 of the first stage can be adjusted so that the delay amounts are larger than in the cases of the multistage-branching-wired-line units 26′ and 26.

Furthermore, in the present example, each logic circuit 27 in the second stage is also arranged at a position different from the position in the cases of the multistage-branching-wired-line units 26′ and 26.

Specifically, with respect to the logic circuits 27 of the second stage, a separation distance Dse2, in the branching directions Dd, between the two logic circuits 27 whose immediately previous wired-line-branching point is common is different from the separation distance Dse2 in the cases of the multistage-branching-wired-line units 26′ and 26.

Here, the two logic circuits 27 whose immediately previous wired-line-branching point is common will be denoted as “paired logic circuits”. In the second stage, two sets of the paired logic circuits exist. Specifically, the two sets include the paired logic circuits located on wired-line paths branched from one of the logic circuits 27 in the first stage, and the paired logic circuits located on wired-line paths branched from the other logic circuit 27 in the first stage.

In the cases of the multistage-branching-wired-line units 26′ and 26, the separation distance Dse2 between the paired logic circuits in the second stage coincides with a separation distance Dsc2 illustrated in the drawing. The separation distance Dsc2 is a separation distance, in the branching directions Dd, between two wired-line-branching points that are among (four) wired-line-branching points in a third stage immediately lower than the second stage and are wired-line-branching points from any one of the sets of the paired logic circuits in the second stage.

In the present example, as illustrated, the separation distance Dse2 between the paired logic circuits in the second stage is different from the separation distance Dsc2. Specifically, the separation distance Dse2 is shorter than the separation distance Dsc2. Consequently, for the paired logic circuits in the second stage, it is possible to arrange the logic circuits 27 closer to each other than in the cases of the multistage-branching-wired-line units 26′ and 26.

Therefore, the logic circuits 27 of the second stage can be adjusted to more increase or decrease the delay amounts than the cases of the multistage-branching-wired-line units 26′ and 26.

Here, in the present example, the setting of the separation distance Dse2 in the second stage as described above is the setting in a stage immediately before the crossing of the wired lines.

Specifically, in the present example, the separation distance Dse2 between the paired logic circuits is made shorter than the separation distance Dsc2 in a stage immediately before the crossing of the wired lines.

When wired lines in a certain space between stages are crossed for a wired-line tree structure, the wired-line length at the crossing portion extends, and the overall wired-line length also increases. The separation distance Dse between the paired logic circuits in the stage immediately before the crossing of the wired lines is made shorter than the separation distance Dcs between the two wired-line-branching points in the immediately lower stage, so that the wired-line length required for branching in the stage immediately before the wired-line crossing can be shortened, and the overall wired-line length can be shortened.

Therefore, the overall wired-line resistance of the multistage-branching-wired-line unit can be reduced, and the power consumption can be reduced.

### 5-4. Fourth Example

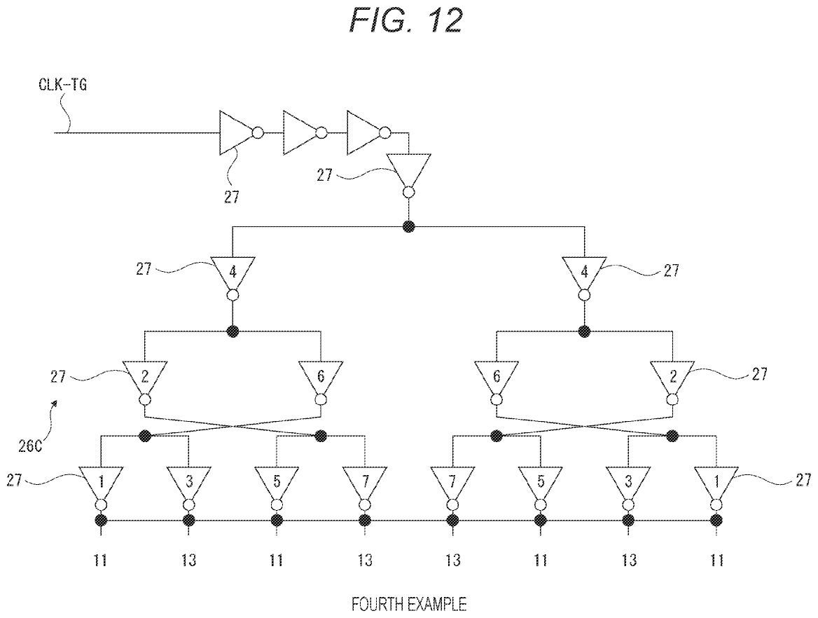

FIG. 12 is an explanatory diagram of a wired-line structure of a multistage-branching-wired-line unit 26C as a fourth example.

In the multistage-branching-wired-line unit 26C, wired output lines of all the logic circuits 27 arranged at a lowermost stage are short-circuited with each other.

The wired output lines of the logic circuits 27 arranged at the lowermost stage are short-circuited with each other, so that it is possible to equalize signal delays for the driving elements Ed connected to the wired output lines. At this time, since in the multistage-branching-wired-line unit of the exemplary embodiment, wired lines in a certain space between stages are crossed, the wired-line short circuit is in a state where the difference in the delay amounts is suppressed, and it is possible to suppress a through current accompanying the wired-line short circuit.

Therefore, the signal propagation delays can be equalized while suppressing an increase in power consumption accompanying the wired-line short circuit.

Note that the wired-line short circuit in the final stage is not necessarily performed for all the wired output lines, and is only required to be performed for only at least certain wired output lines.

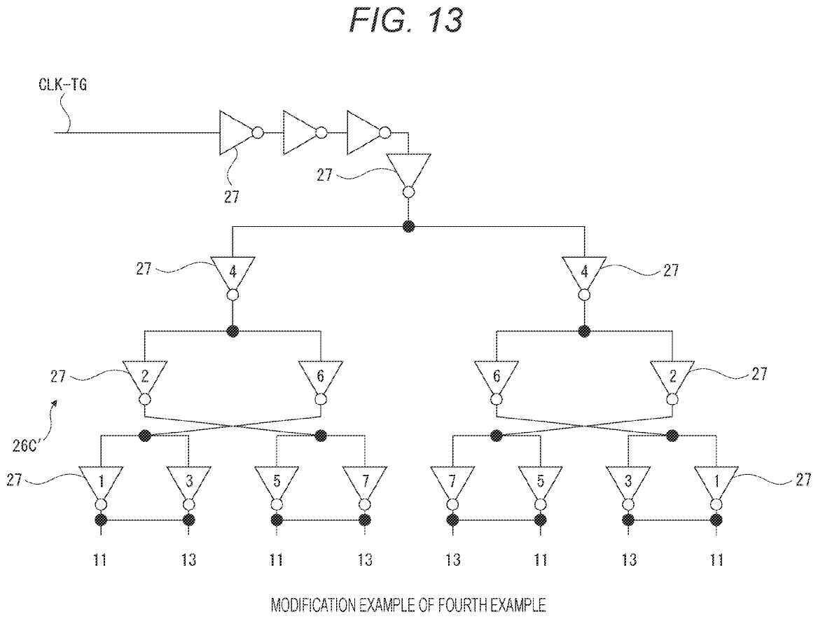

FIG. 13 illustrates a wired-line structure example of a multistage-branching-wired-line unit 26C′ in which only certain wired output lines are short-circuited with each other. In FIG. 13, as an example, only wired output lines of paired logic circuits in a lowermost stage are short-circuited with each other.

Note that an example of partial wired-line short circuit is not limited to the example, and other forms, such as short-circuiting wired output lines of the logic circuits 27 with each other that have no paired-logic-circuit relationship, can be adopted.

### 5-5. Fifth Example

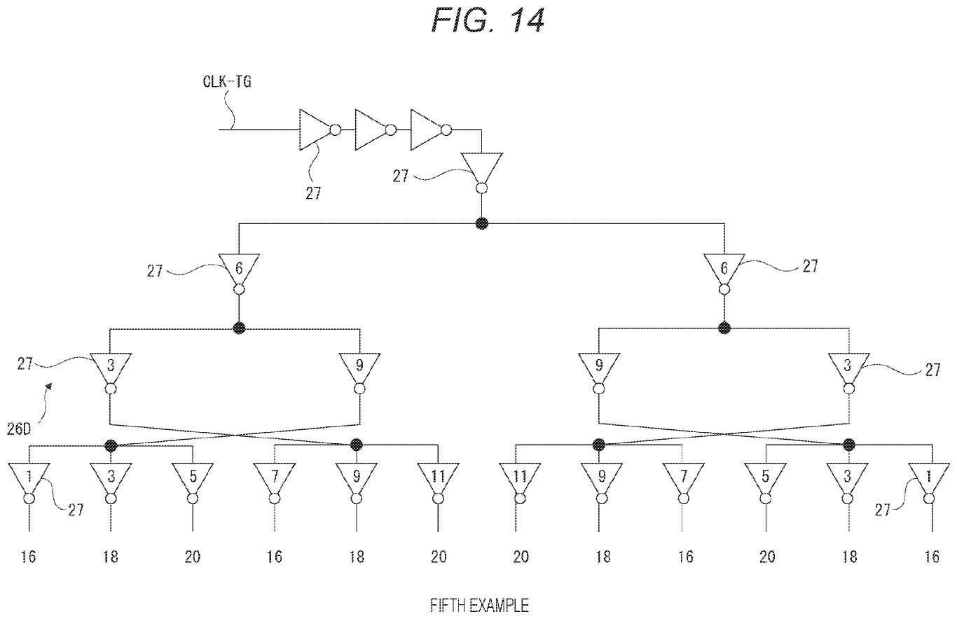

FIG. 14 is an explanatory diagram of a wired-line structure of a multistage-branching-wired-line unit 26D as a fifth example.

In the multistage-branching-wired-line unit 26D, the number of wired-line branching at a lowermost stage is changed from “2” illustrated so far to “3” or more. FIG. 14 illustrates, as one example, an example in which the number of wired-line branching at the lowermost stage is “3”. In this case, the equal-wired-line-length property is not secured in the lowermost stage, but the influence can be made small because of the lowermost stage.

### 5-6. Sixth Example

FIG. 15 is an explanatory diagram of a wired-line structure of a multistage-branching-wired-line unit 26E as a sixth example.

In the multistage-branching-wired-line unit 26E, the number of stages of wired-line branching is increased from 3 so far to 4. Note that in FIG. 15, for the convenience of illustration, only the structure on one side after first branching is illustrated for the multistage branching structure.

According to the illustrated wired-line structure of the multistage-branching-wired-line unit 26E, the maximum value is “37” and the minimum value is “27” as the delay amount of every wired-line path (delay amount of every driving element Ed). Note that numerical values indicated in parentheses indicate delay amounts in a case of a structure in which wired-line crossing is not performed, and specifically, the maximum value is “49” (8+12+14+15), and the minimum value is “15” (8+4+2+1).

Here, in the multistage-branching-wired-line unit 26E, wired-line crossing is performed not only in a space between the lowermost stage (fourth stage) and a stage (third stage) immediately upper than the lowermost stage, but also in a space between a second stage and the third stage. Therefore, the delay amounts are more equalized than a case where wired lines are crossed only in a space between a lowermost stage and a stage immediately upper than the lowermost stage. As specific numerical values, in a case where the wired lines are crossed only in a space between the lowermost stage and the stage immediately upper than the lowermost stage, the maximum value of the delay amount of every wired-line path is “45” (8+12+10+15), and the minimum value is “19” (8+4+6+1), whereas in a case where the wired lines are also crossed in a space between the second stage and third stage, the maximum value and the minimum value are “37” and “27” as described above.

By performing wired-line crossing in a plurality of spaces between stages, the number of adjustment elements of the delay amounts is more increased than a case where wired-line crossing is performed in only one space between stages, and the degree of freedom in adjusting the delay amounts can be improved.

Particularly by performing wired-line crossing in a plurality of spaces between stages after the second stage, as in the example in FIG. 15, the delay amounts can be more equalized than a case where wired-line crossing is performed only in one space between stages.

### 5-7. Seventh Example

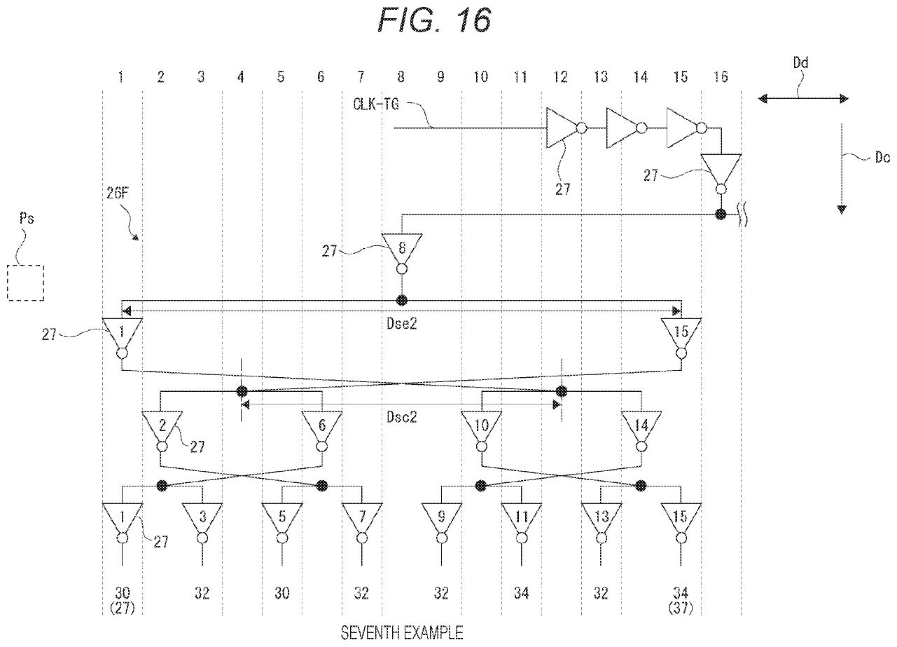

FIG. 16 is an explanatory diagram of a wired-line structure of a multistage-branching-wired-line unit 26F as a seventh example.

The multistage-branching-wired-line unit 26F is the multistage-branching-wired-line unit 26E illustrated in FIG. 15 in which a separation distance Dse2 between paired logic circuits of the second stage is changed from a separation distance Dsc2 (separation distance between two wired-line-branching points in the immediately lower stage) in order to enhance the effect of equalizing the delay amounts. Specifically, in the illustrated example, the separation distance Dse2 is made wider than the separation distance Dsc2 by offsetting the positions of the paired logic circuits of the second stage in an inward direction and an outward direction of the multistage branching structure, respectively. More specifically, one logic circuit 27 of the paired logic circuits of the second stage is arranged at a position of “1” the closest to a supply position Ps (having a smallest separation distance in branching directions Dd), and the other logic circuit 27 is arranged at a position of “15” the farthest from the supply position Ps.

In this case, the maximum value and the minimum value of the delay amount of every wired-line path are “34” (8+1+10+15) and “30” (8+15+6+1) as illustrated, and the delay amount of every wired-line path can be more equalized than in the case of the multistage-branching-wired-line unit 26E in which the maximum value and the minimum value are “37” and “27”, respectively.

A separation distance Dse of paired logic circuits in a particular stage is made different from a separation distance Dsc between two wired-line-branching points in a stage immediately lower than the particular stage (separation distance, in branching directions Dd, between the wired-line-branching points from the paired logic circuits), so that the distance from a supply position Ps can be adjusted for the paired logic circuits.

Therefore, the signal propagation delay amount for each driving element Ed can be adjusted.

Note that in a case where a separation distance Dse of a particular stage is made longer as illustrated in FIG. 16, the wired-line length in the stage becomes longer, but a logic circuit for driving may be arranged in a portion where the wired line becomes longer in this manner.

### 5-8. Eighth Example

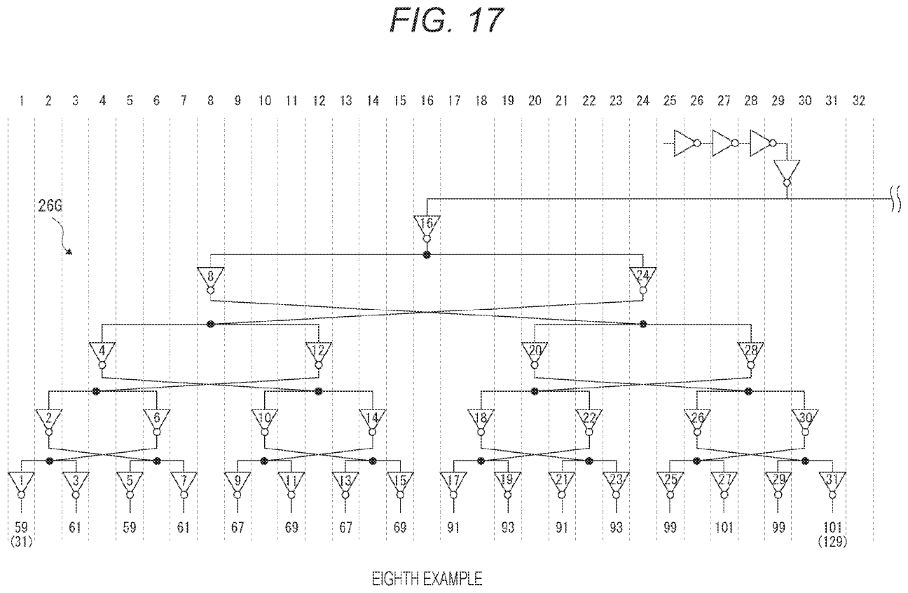

FIG. 17 is an explanatory diagram of a wired-line structure of a multistage-branching-wired-line unit 26G as an eighth example.

In the multistage-branching-wired-line unit 26F, the number of stages of wired-line branching is 5. Note that also in FIG. 17, for the convenience of illustration, only the structure on one side after first branching is illustrated for the multistage branching structure.

FIG. 17 illustrates an example in which crossing of wired lines is performed in a space between a second stage and a third stage, a space between the third stage and a fourth stage, and a space between the fourth stage and a fifth stage. In this case, the maximum value of the delay amount of every wired-line path is “101” (16+8+20+26+31), and the minimum value is “59” (16+24+12+6+1). In a case where the number of stages of wired-line branching is five and wired-line crossing is not performed at all, the maximum value and the minimum value are “129” (16+24+28+30+31) and “31” (16+8+4+2+1) as indicated in parentheses in the drawing.

In this manner, the signal propagation delay amount for each driving element Ed is equalized by the wired-line crossing.

### 6. Example of Wired-Line-Crossing Structure

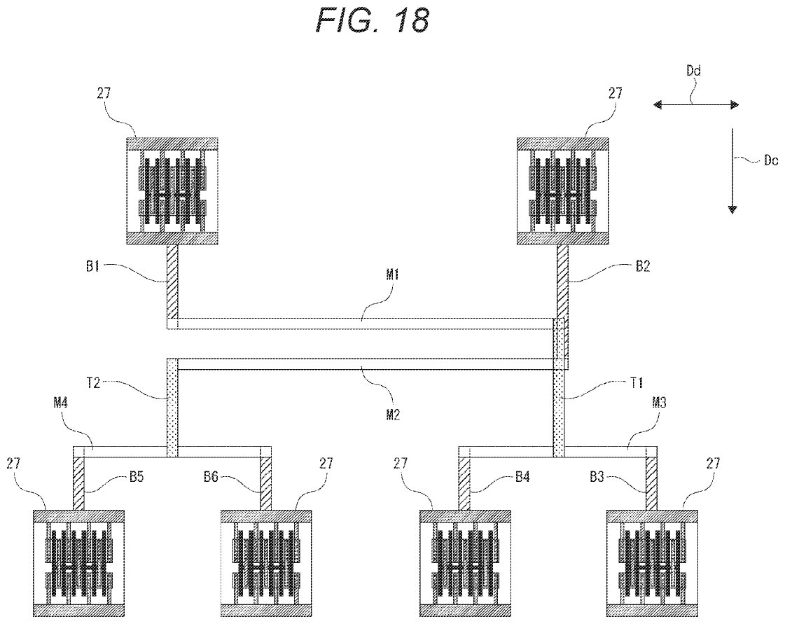

FIG. 18 is an explanatory diagram of an example of a wired-line-crossing structure.

It is conceivable that crossing of wired lines is performed using a plurality of wired-line layers. In the drawing, an example in which wired-line crossing is implemented using three wired-line layers is illustrated for a wired-line-crossing structure in, for example, a space between a second stage and a third stage.

Wired lines B that are hatched represent wired lines formed in a lowermost wired-line layer among the three wired-line layers. Furthermore, wired lines M that are outlined and wired lines T that are dotted represent wired lines formed in an intermediate wired-line layer and an uppermost wired-line layer among the three wired-line layers, respectively.

As illustrated in the drawing, one end of a wired line B1 extending in a branching chain direction Dc is connected to one logic circuit 27 of logic circuits 27 of the second stage (a logic circuit 27 on the left side in the drawing), one end of a wired line M1 extending in branching directions Dd is interlayer-connected to the other end of the wired line B1, and further one end of a wired line T1 extending in the branching chain direction Dc is interlayer-connected to the other end of the wired line M1. Then, the other end of the wired line T1 is interlayer-connected to a central portion of a wired line M3 extending in the branching directions Dd, one end of a wired line B3 extending in the branching directions Dd is interlayer-connected to one end of the wired line M3, and a first logic circuit 27 in the third stage (a rightmost logic circuit 27 in the drawing) is connected to the other end of the wired line B3. Furthermore, one end of a wired line B4 extending in the branching directions Dd is interlayer-connected to the other end of the wired line M3, and a second logic circuit 27 in the third stage (a second logic circuit 27 from the right in the drawing) is connected to the other end of the wired line B4.

Furthermore, one end of a wired line B2 extending in the branching chain direction Dc is connected to the other logic circuit 27 of the logic circuits 27 of the second stage (a logic circuit 27 on the right side in the drawing), one end of a wired line M2 extending in the branching directions Dd is interlayer-connected to the other end of the wired line B2, and further one end of a wired line T2 extending in the branching chain direction Dc is interlayer-connected to the other end of the wired line M2. Then, the other end of the wired line T2 is interlayer-connected to a central portion of a wired line M4 extending in the branching directions Dd, one end of a wired line B5 extending in the branching directions Dd is interlayer-connected to one end of the wired line M4, and a third logic circuit 27 in the third stage (a leftmost logic circuit 27 in the drawing) is connected to the other end of the wired line B5. Furthermore, one end of a wired line B6 extending in the branching directions Dd is interlayer-connected to the other end of the wired line M4, and a fourth logic circuit 27 in the third stage (a second logic circuit 27 from the left in the drawing) is connected to the other end of the wired line B6.

Note that, in the drawing, the position, in the branching directions Dd, of the wired line B2 is slightly shifted toward the right side of the drawing, considering visibility, but the positions, in the branching directions Dd, of the wired line B2 and the wired line T1 are made to coincide with each other on the premise that the equal-wired-line-length property is secured.

Furthermore, regarding the wired lines M1 and M2, it is desirable to provide a wired-line interval as much as possible in order to reduce the line-to-line capacitance.

### 7. Modification Examples

### 7-1. First Modification Example

Here, in a case where distance measurement is performed by a ToF scheme, particularly an indirect ToF scheme, it is important to secure timing synchronization between the light emission side and the light reception side in order to improve distance measurement performance.

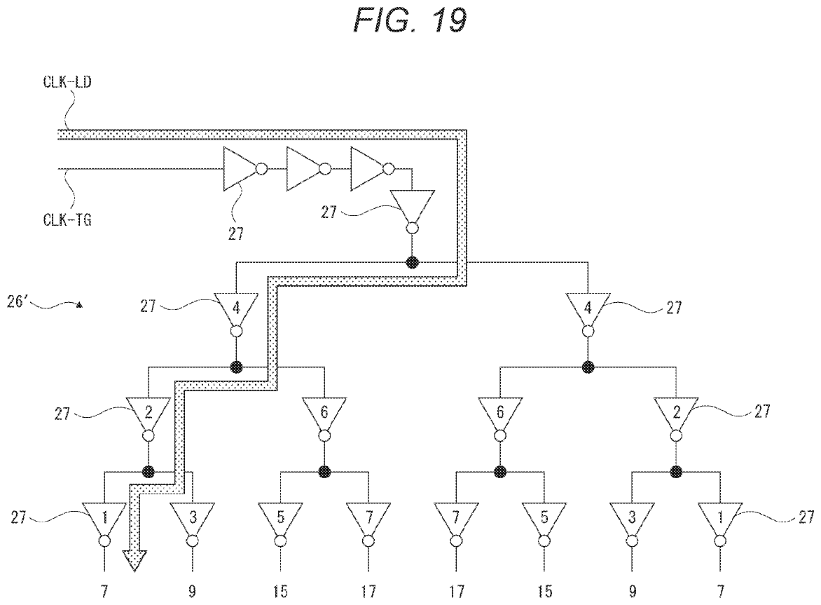

Therefore, as illustrated in FIG. 19, a wired line for the light-emission-side clock signal CLK-LD is conventionally formed along any one of wired-line paths in the multistage-branching-wired-line unit 26′. Specifically, FIG. 19 illustrates an example in which the wired line for the light-emission-side clock signal CLK-LD is disposed along a wired-line path passing through the logic circuit 27 located on the leftmost side of the drawing at a lowermost stage to correspond to a case where a light emission element in the light emission unit 2 exists on the left side of the drawing.

Therefore, it is possible to equalize the signal delay amounts not only on the light reception side but also between the light reception side and the light emission side, and in distance measurement by a ToF scheme, it is possible to enhance the synchronization between the light emission timing and the light reception timing and improve the distance measurement performance.

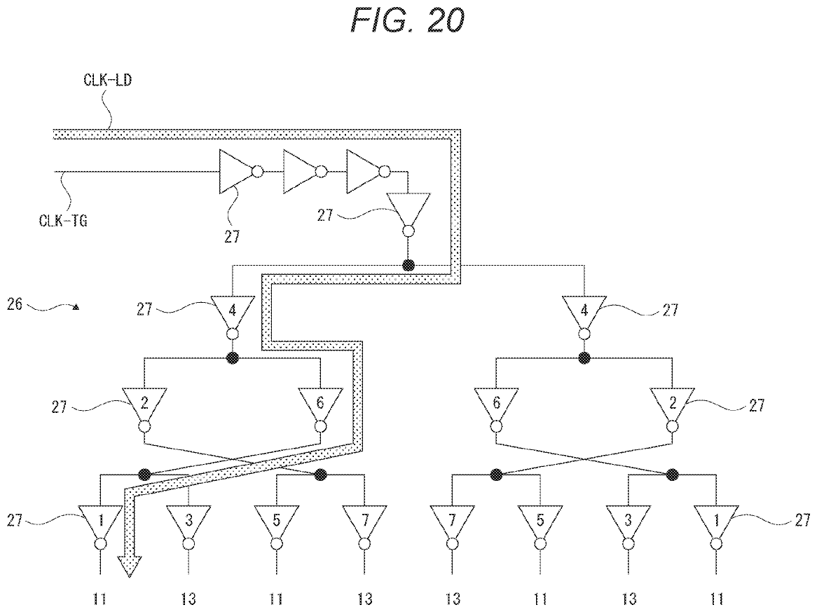

In the first modification example, such a technique of wiring a wired line for the light-emission-side clock signal CLK-LD is applied to the multistage-branching-wired-line unit 26, and a specific example of the wired-line structure is illustrated in FIG. 20.

In this case, as illustrated, a wired line for the light-emission-side clock signal CLK-LD is formed along any one wired-line path of each wired-line path in the multistage-branching-wired-line unit 26. FIG. 20 also illustrates an example in which the wired line for the light-emission-side clock signal CLK-LD is disposed along a wired-line path passing through the logic circuit 27 located on the leftmost side of the drawing at a lowermost stage to correspond to a case where a light emission element in the light emission unit 2 exists on the left side of the drawing. In this case, the wired line for the light-emission-side clock signal CLK-LD is formed along the wired-line path passing through a crossing portion of the wired lines.

In the case of FIG. 20 in which wired lines are crossed, the signal delay amounts on the light reception side are more equalized than in the case of FIG. 19 in which wired lines are not crossed. Therefore, according to the configuration illustrated in FIG. 20, it is possible to more reduce the difference in the signal delay amount between the light emission side and the light reception side than a case where a wired line for the light-emission-side clock signal CLK-LD is provided along without crossing wired lines, as illustrated in FIG. 19, and it is possible to improve the distance measurement performance.

### 7-2. Second Modification Example

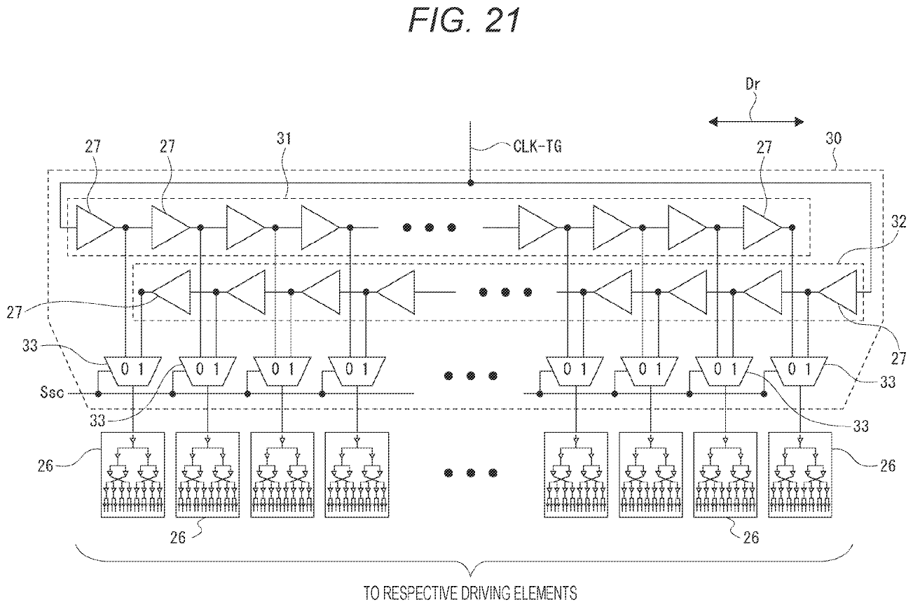

Here, in order to enhance the equal-delay property of a signal propagating to each driving element Ed, a delay-amount averaging circuit 30 as illustrated in FIG. 21 can also be provided.

As illustrated, the delay-amount averaging circuit 30 includes a first logic circuit group 31 and a second logic circuit group 32 into each of which the light-reception-side clock signal CLK-TG is input, and a plurality of multiplexers 33.

The first logic circuit group 31 includes a plurality of the logic circuits 27 connected in series in one direction, and propagates the light-reception-side clock signal CLK-TG via the logic circuits 27 in the above-described one direction. The second logic circuit group 32 includes a plurality of the logic circuits 27 connected in series in a direction opposite to the above-described one direction, and propagates the light-reception-side clock signal CLK-TG via the logic circuits 27 in the above-described opposite direction. In the first logic circuit group 31 and the second logic circuit group 32, the numbers of the logic circuits 27 arranged correspond to each other.

Here, a direction parallel to the array direction of the logic circuits 27 in each of the first logic circuit group 31 and the second logic circuit group 32 is denoted as an “array direction Dr” as illustrated.

The number of the multiplexers 33 provided is the same as the number of the logic circuits 27 arranged in each of the first logic circuit group 31 and the second logic circuit group 32, and the plurality of multiplexers 33 is arrayed in the array direction Dr.

Here, regarding the logic circuits 27 of the first logic circuit group 31, the logic circuits 27 of the second logic circuit group 32, and the multiplexers 33, the arrangement positions in the array direction Dr are defined as a first-column position to an nth-column position in order from the left side of the drawing.

In the multiplexer 33 of the first column, the output of the logic circuit 27 of the first column in the first logic circuit group 31 is input into one of input terminals, and the output of the logic circuit 27 of the first column in the second logic circuit group 32 is input into the other input terminal. Furthermore, in the x-th (x=1 to n) multiplexer 33, the output of the logic circuit 27 of the x-th column in the first logic circuit group 31 is input into one of input terminals, and the output of the logic circuit 27 of the x-th column in the second logic circuit group 32 is input into the other input terminal, in such a manner that the output of the logic circuit 27 of the second column in the first logic circuit group 31 is input into one of input terminals of the multiplexer 33 of the second column, and the output of the logic circuit 27 of the second column in the second logic circuit group 32 is input into the other input terminal.

In the delay-amount averaging circuit 30, the output of each multiplexer 33 is alternately switched by a selection control signal Ssc in the drawing. Therefore, a low-delay signal and a high-delay signal are alternately output as the light-reception-side clock signal CLK-TG output from each multiplexer 33, and the delay amounts are averaged in the time direction.

However, in the delay-amount averaging circuit 30 as described above, there is a possibility that local mismatch of the logic circuits 27, or the like makes it difficult to enhance the effect of equalizing the delay amounts.

Therefore, as illustrated, the output of each multiplexer 33 is propagated to each driving element Ed through the multistage-branching-wired-line unit 26 instead of the conventional multistage-branching-wired-line unit 26′. That is, using the multistage-branching-wired-line unit 26 instead of the multistage-branching-wired-line unit 26′ having a conventional tree structure is not a direct measure against the local mismatch of the delay-amount averaging circuit 30, but equalizes the delay amounts.

### 7-3. Other Modification Examples

Note that exemplary embodiments are not limited to the specific examples described above, and various modification examples may be adopted.

For example, regarding each example of the first to eighth examples, the first modification example, and the second modification example described above, at least part or all can be combined. For example, as a combination of the sixth example (FIG. 15) and the first modification example (FIG. 20), conceivable is a configuration in which in a case where crossing of the wired lines is performed in a plurality of spaces between the stages, a wired line for the light-emission-side clock signal CLK-LD is disposed along a wired-line path passing through the wired-line-crossing portions. Alternatively, as a combination of the sixth example (FIG. 15) and the fourth example (FIGS. 12 and 13), conceivable is a configuration in which in a case where the number of stages of wired-line branching is “4”, wired output lines from at least certain logic circuits 27 in the lowermost stage are short-circuited with each other, and as combinations of the seventh example (FIG. 16) and the fifth example (FIG. 14), conceivable are a configuration in which the number of wired-line branching in the lowermost stage is “3” or more while the paired logic circuits in the second stage are arranged so that the separation distance Dse2≠the separation distance Dsc2, and the like.

Furthermore, the inverter circuit has been exemplified above as an example of the logic circuit 27, but as the logic circuit 27, for example, a buffer circuit, a NAND gate circuit or an AND gate circuit having one side into which an enable signal is input, a NAND gate circuit or an AND gate circuit having one side in which voltage is fixed, or the like can also be used.

Furthermore, the above description is on the premise that the supply positions Ps (common supply positions) of the power sources to the logic circuits 27 are side portions, in the branching directions Dd, of the piled-branching-wired-line unit. However, even when the supply position Ps is another position, such as a central position, in the branching directions Dd, of the piled-branching-wired-line unit, the delay amount of every logic circuit 27 similarly varies, and due to the variation, the equal-delay signal property and the like similarly decrease. That is, the wired-line crossing as the exemplary embodiment can be also suitably applied to a case where the supply position Ps is a position except the side portions, in the branching directions Dd, of the piled-branching-wired-line unit.

### 8. Summary of Exemplary Embodiments

As described above, a signal processing device (transfer gate driving unit 12) as an exemplary embodiment includes: a multistage-branching-wired-line unit (multistage-branching-wired-line unit 26, 26A, 26B, 26C, 26C′, 26D, 26E, 26F, or 26G) that supplies the same signal to a plurality of target elements (driving elements Ed) via multistage-branched wired lines; and a logic circuit (logic circuit 27) arranged at each of stages of the multistage-branching-wired-line unit, in which the wired lines in at least a certain space between the stages in the multistage-branching-wired-line unit cross each other.

Therefore, it is possible to prevent a path passing through only the logic circuits with smaller delay amounts, and a path passing through only the logic circuits with larger delay amounts from existing together as signal supply paths for the respective target elements.

Therefore, the signal propagation delays for the target elements can be equalized.

Furthermore, in the signal processing device as the exemplary embodiment, in the multistage-branching-wired-line unit (multistage-branching-wired-line unit 26B or 26F), branching directions (branching directions Dd) of the wired lines coincide with each other in each stage, and a separation distance (separation distance Dse), in the branching directions, between paired logic circuits that are among logic circuits arranged at at least one of the stages in the multistage-branching-wired-line unit and whose immediately previous wired-line-branching point is common, is different from a separation distance (separation distance Dsc), in the branching directions, between two wired-line-branching points that are among wired-line-branching points in the stage immediately lower than the one of the stages, and are wired-line-branching points from the paired logic circuits (see the third example: FIG. 11 and the seventh example: FIG. 16).

Therefore, the distance from a power source supply position can be adjusted for the logic circuits arranged at the at least one of the stages.

Therefore, the signal propagation delay amount for each target element can be adjusted.

Moreover, in the signal processing device as the exemplary embodiment, the one of the stages is the stage immediately before the crossing of the wired lines, and the separation distance, in the branching directions, between the paired logic circuits in the one of the stages is shorter than the separation distance, in the branching directions, between the two wired-line-branching points in the stage immediately lower than the one of the stages (see the third example: FIG. 11).

When wired lines in a certain space between stages are crossed for a wired-line tree structure, the wired-line length at the crossing portion extends, and thus the overall wired-line length also increases. As described above, with respect to the separation distance, in the branching directions, the separation distance between the paired logic circuits in the stage immediately before the crossing of the wired lines is made shorter than the separation distance between the two wired-line-branching points in the immediately lower stage, so that the wired-line length required for branching in the stage immediately before the crossing can be shortened, and the overall wired-line length can be shortened.

Therefore, the overall wired-line resistance of the multistage-branching-wired-line unit can be reduced, and the power consumption can be reduced.

Furthermore, in the signal processing device as the exemplary embodiment, in the multistage-branching-wired-line unit, wired output lines of at least certain logic circuits among the logic circuits arranged at a lowermost one of the stages are short-circuited with each other (see the fourth example: FIGS. 12 and 13).

The wired output lines of the logic circuits arranged at the lowermost stage are short-circuited with each other, so that it is possible to equalize signal delays for the target elements connected to the wired output lines. At this time, since in the multistage-branching-wired-line unit, the wired lines in the certain space between the stages are crossed, the wired-line short circuit is in a state where the difference in the delay amounts is suppressed, and it is possible to suppress a through current accompanying the wired-line short circuit.

Therefore, the signal propagation delays can be equalized while suppressing an increase in power consumption accompanying the wired-line short circuit.

Furthermore, in the signal processing device as the exemplary embodiment, in the lowermost stage, the short-circuiting of the wired output lines with each other is only among certain ones of the wired output lines (see FIG. 13).

The through current is suppressed by short-circuiting not all but only the certain wired output lines.

Therefore, power consumption can be reduced.

Moreover, in the signal processing device as the exemplary embodiment, in the lowermost stage, all the wired output lines are short-circuited with each other (see FIG. 12).

Therefore, the effect of equalizing the delay amounts due to the wired-line short circuit is enhanced.

Therefore, the signal propagation delays for the target elements can be further equalized.

Furthermore, in the signal processing device as the exemplary embodiment, the wired lines are crossed in a plurality of spaces between the stages in the multistage-branching-wired-line unit (see the second example: FIG. 10, the sixth example: FIG. 15, and the eighth example: FIG. 17).

By performing the wired-line crossing in the plurality of spaces between the stages, the number of adjustment elements of the delay amounts is more increased than a case where the wired-line crossing is performed in only one space between the stages.

Therefore, the degree of freedom in adjusting the delay amounts can be improved.

A sensing module (sensing module 6) as an exemplary embodiment includes: a pixel array unit (pixel array unit 11) in which a plurality of pixels (pixels Px) including light reception elements is two-dimensionally arrayed; a multistage-branching-wired-line unit (multistage-branching-wired-line unit 26, 26A, 26B, 26C, 26C′, 26D, 26E, 26F, or 26G) that supplies the same signal, via multistage-branched wired lines, to a plurality of driving elements (driving element Ed) that drives the plurality of pixels in the pixel array unit; and a logic circuit (logic circuit 27) arranged at each of stages of the multistage-branching-wired-line unit, in which the wired lines in at least a certain space between the stages in the multistage-branching-wired-line unit cross each other.

Therefore, it is possible to prevent a path passing through only the logic circuits with smaller delay amounts, and a path passing through only the logic circuits with larger delay amounts from existing together as signal supply paths for the respective driving elements.

Therefore, the signal propagation delays for the driving elements can be equalized.

Furthermore, the sensing module as the exemplary embodiment performs distance measurement by a ToF scheme.

Therefore, in the sensing module that performs distance measurement by the ToF scheme, it is possible to equalize the signal propagation delays for the driving elements.

Therefore, the accuracy of pixel driving can be improved, and the distance measurement performance can be improved.

Moreover, the sensing module as the exemplary embodiment further includes a light emission unit (light emission unit 2) that emits light for distance measurement, in which a wired-line path for a light emission timing signal that indicates a light emission timing of the light emission unit is formed along a wired-line path that is among wired-line paths for the same signal in the multistage-branching-wired-line unit and that passes through a crossing portion of the wired lines (see the first modification example: FIG. 20).

Therefore, the signal propagation delay equalization between a signal for the elements for driving the pixels and the light emission timing signal can be performed.

Therefore, in the distance measurement by the ToF scheme, synchronization between the light emission timing and the light reception timing can be improved, and the distance measurement performance can be improved.

Note that effects described in the present description are absolutely illustrative and not limitative, and other effects may be provided.

### 9. Present Technology

Note that the present technology may be configured as follows:

(1)

A signal processing device including:

a multistage-branching-wired-line unit that supplies the same signal to a plurality of target elements via multistage-branched wired lines; and

a logic circuit arranged at each of stages of the multistage-branching-wired-line unit,

in which the wired lines in at least a certain space between the stages in the multistage-branching-wired-line unit cross each other.

(2)

The signal processing device according to (1) described above, in which

in the multistage-branching-wired-line unit, branching directions of the wired lines coincide with each other in each stage, and

a separation distance, in the branching directions, between paired logic circuits that are among logic circuits arranged at at least one of the stages in the multistage-branching-wired-line unit and whose immediately previous wired-line-branching point is common, is different from a separation distance, in the branching directions, between two wired-line-branching points that are among wired-line-branching points in the stage immediately lower than the one of the stages, and are wired-line-branching points from the paired logic circuits.

(3)

The signal processing device according to (2) described above, in which

the one of the stages is the stage immediately before the crossing of the wired lines, and

the separation distance, in the branching directions, between the paired logic circuits in the one of the stages is shorter than the separation distance, in the branching directions, between the two wired-line-branching points in the stage immediately lower than the one of the stages.

(4)

The signal processing device according to any one of (1) to (3) described above, in which

in the multistage-branching-wired-line unit, wired output lines of at least certain logic circuits among the logic circuits arranged at a lowermost one of the stages are short-circuited with each other.

(5)

The signal processing device according to (4) described above, in which

in the lowermost stage, the short-circuiting of the wired output lines with each other is only among certain ones of the wired output lines.

(6)

The signal processing device according to (5) described above, in which

in the lowermost stage, all the wired output lines are short-circuited with each other.

(7)

The signal processing device according to any one of (1) to (6) described above, in which

the wired lines are crossed in a plurality of spaces between the stages in the multistage-branching-wired-line unit.

(8)

A sensing module including:

a pixel array unit in which a plurality of pixels including light reception elements is two-dimensionally arrayed;

a multistage-branching-wired-line unit that supplies the same signal, via multistage-branched wired lines, to a plurality of driving elements that drives the plurality of pixels in the pixel array unit; and

a logic circuit arranged at each of stages of the multistage-branching-wired-line unit,

in which the wired lines in at least a certain space between the stages in the multistage-branching-wired-line unit cross each other.

(9)

The sensing module according to (8) described above,

performing distance measurement by a ToF scheme.

(10)

The sensing module according to (9) described above, further including

a light emission unit that emits light for distance measurement,

in which a wired-line path for a light emission timing signal that indicates a light emission timing of the light emission unit is formed along a wired-line path that is among wired-line paths for the same signal in the multistage-branching-wired-line unit and that passes through a crossing portion of the wired lines.

### REFERENCE SIGNS LIST

1 Sensor unit (Sensor device)
2 Light emission unit
3 Control unit
6 Sensing module
11 Pixel array unit
12 Transfer gate driving unit
13 Perpendicular driving unit
14 System control unit
Column processing unit
16 Horizontal driving unit
17 Signal processing unit
18 Data storage unit
20 Row driving line
21 Gate driving line
22 Perpendicular signal line
Px Pixel
Cl Light emission cycle
Pm Modulation period
Pr Light reception period
CLK-TG Light-reception-side clock signal
CLK-LD Light-emission-side clock signal
25 Driver unit
26, 26A, 26B, 26C, 26C′, 26D, 26E, 26F, 26G Multistage-branching-wired-line unit
27 Logic circuit
Ps Supply position
Dd Branching directions
Dc Branching chain direction

1. A signal processing device comprising:
a multistage-branching-wired-line unit that supplies a same signal to a plurality of target elements via multistage-branched wired lines; and
a logic circuit arranged at each of stages of the multistage-branching-wired-line unit,
wherein the wired lines in at least a certain space between the stages in the multistage-branching-wired-line unit cross each other.

2. The signal processing device according to claim 1,
wherein, in the multistage-branching-wired-line unit, branching directions of the wired lines coincide with each other in each stage, and
a separation distance, in the branching directions, between paired logic circuits that are among logic circuits arranged at at least one of the stages in the multistage-branching-wired-line unit and whose immediately previous wired-line-branching point is common, is different from a separation distance, in the branching directions, between two wired-line-branching points that are among wired-line-branching points in the stage immediately lower than the one of the stages, and are wired-line-branching points from the paired logic circuits.

3. The signal processing device according to claim 2,
wherein the one of the stages is the stage immediately before the crossing of the wired lines, and
the separation distance, in the branching directions, between the paired logic circuits in the one of the stages is shorter than the separation distance, in the branching directions, between the two wired-line-branching points in the stage immediately lower than the one of the stages.

4. The signal processing device according to claim 1,
wherein, in the multistage-branching-wired-line unit, wired output lines of at least certain logic circuits among the logic circuits arranged at a lowermost one of the stages are short-circuited with each other.

5. The signal processing device according to claim 4,
wherein, in the lowermost stage, the short-circuiting of the wired output lines with each other is only among certain ones of the wired output lines.

6. The signal processing device according to claim 5,
wherein, in the lowermost stage, all the wired output lines are short-circuited with each other.

7. The signal processing device according to claim 1,
wherein the wired lines are crossed in a plurality of spaces between the stages in the multistage-branching-wired-line unit.

8. A sensing module comprising:
a pixel array unit in which a plurality of pixels including light reception elements is two-dimensionally arrayed;
a multistage-branching-wired-line unit that supplies a same signal, via multistage-branched wired lines, to a plurality of driving elements that drives the plurality of pixels in the pixel array unit; and
a logic circuit arranged at each of stages of the multistage-branching-wired-line unit,
wherein the wired lines in at least a certain space between the stages in the multistage-branching-wired-line unit cross each other.

9. The sensing module according to claim 8,
performing distance measurement by a ToF scheme.

10. The sensing module according to claim 9, further comprising
a light emission unit that emits light for distance measurement,
wherein a wired-line path for a light emission timing signal that indicates a light emission timing of the light emission unit is formed along a wired-line path that is among wired-line paths for the same signal in the multistage-branching-wired-line unit and that passes through a crossing portion of the wired lines.
